(19) United States
(12) Patent Application Publication
(10) Pub. No.: US 2019/0288240 A1
(43) Pub. Date: Sep. 19, 2019

(54) CIRCULARLY POLARIZING PLATE, AND ORGANIC ELECTROLUMINESCENT DISPLAY DEVICE

(71) Applicant: FUJIFILM Corporation, Tokyo (JP)

(72) Inventors: Kunihiro ATSUMI, Kanagawa (JP); Yukito SAITOH, Kanagawa (JP)

(73) Assignee: FUJIFILM Corporation, Tokyo (JP)

(21) Appl. No.: 16/420,756

(22) Filed: May 23, 2019

Related U.S. Application Data
(63) Continuation of application No. PCT/JP2017/045509, filed on Dec. 19, 2017.

(30) Foreign Application Priority Data
Dec. 26, 2016 (JP) 2016-251811
Dec. 8, 2017 (JP) 2017-236196

(51) Int. Cl. H01L 51/52; G02B 5/30

(52) U.S. Cl. CPC H01L 51/5281; G02B 5/3025; G02B 5/3083

(57) ABSTRACT

The present invention provides a circularly polarizing plate applied to a display device, which further suppresses reflection of external light and a change in tint when viewed in an oblique direction, and an organic electroluminescent display device. The circularly polarizing plate has a polarizer, a λ/2 plate, and a λ/4 plate in this order, in which an angle formed between an absorption axis of the polarizer and an in-plane slow axis of the λ/4 plate is in a range of 20° to 70°, an Nz factor of the λ/4 plate is 0.30 to 0.70, the absorption axis of the polarizer and an in-plane slow axis of the λ/2 plate are orthogonal or parallel to each other, at Nz factor of the λ/2 plate being 0.10 to 0.40, and the Nz factor of the λ/2 plate being 0.60 to 0.90, respectively.

### CROSS-REFERENCE TO RELATED APPLICATIONS

This application is a Continuation of PCT International Application No. PCT/JP2017/045509 filed on Dec. 19, 2017, which claims priority under 35 U.S.C. § 119(a) to Japanese Patent Application No. 2016-251811 filed on Dec. 26, 2016 and Japanese Patent Application No. 2017-236196 filed on Dec. 8, 2017. Each of the above applications is hereby expressly incorporated by reference, in its entirety, into the present application.

### BACKGROUND OF THE INVENTION

### 1. Field of the Invention

The present invention relates to a circularly polarizing plate and an organic electroluminescent display device.

### 2. Description of the Related Art

Conventionally, in order to suppress adverse effects of reflection of external light, a circularly polarizing plate has been used in an organic electroluminescent (EL) display device or the like. As a circularly polarizing plate, for example, as described in WO2015/166991A, an aspect in which a first optically anisotropic layer, a λ/4 plate, and a polarizer are combined is disclosed. In the embodiment of WO2015/166991A, a λ/2 plate having an Nz factor of 0 or 1 is used as the first optically anisotropic layer.

### SUMMARY OF THE INVENTION

On the other hand, in recent years, in a display device typified by an organic EL display device, further improvement in viewing angle characteristics has been required. More specifically, in a display device including a circularly polarizing plate, it is required to further reduce reflection of external light in the case of being viewed in an oblique direction.

The present inventors have examined the external light reflection characteristics of the organic EL display device including the circularly polarizing plate described WO2015/166991A and found that the suppression of the reflection of external light in the case of being viewed in an oblique direction does not reach the recently required level and further improvement is required.

In addition, when the display device is viewed in an oblique direction, it is also required that a change in tint is small in the case where the display device is viewed while changing the azimuthal angle. That is, it is required that a change in tint in the case of being viewed in the oblique direction is further suppressed.

The present invention is made in consideration of the above circumstances and an object thereof is to provide a circularly polarizing plate that in the case where the circularly polarizing plate is applied to a display device, further suppresses reflection of external light and a change in tint when viewed in an oblique direction.

Another object of the present invention is to provide an organic EL display device having the circularly polarizing plate.

As a result of intensive investigations on problems in the related art, the present inventors have found that the above problems can be solved by using a circularly polarizing plate having a predetermined configuration.

That is, the present inventors have found that the above objects can be achieved by adopting the following configurations.

(1) An organic electroluminescent display device comprising: an organic electroluminescent display panel; and a circularly polarizing plate arranged on the organic electroluminescent display panel,

in which the circularly polarizing plate has a polarizer, a λ/2 plate, and λ/4 plate in this order,

an angle formed between an absorption axis of the polarizer and an in-plane slow axis of the λ/4 plate is in a range of 200 to 700,

an Nz factor of the λ/4 plate is 0.30 to 0.70,

the absorption axis of the polarizer and an in-plane slow axis of the λ/2 plate are orthogonal or parallel to each other,

in a case where the absorption axis of the polarizer and the in-plane slow axis of the λ/2 plate are orthogonal to each other, an Nz factor of the λ/2 plate is 0.10 to 0.40, and

in a case where the absorption axis of the polarizer and the in-plane slow axis of the λ/2 plate are parallel to each other, the Nz factor of the λ/2 plate is 0.60 to 0.90.

(2) The organic electroluminescent display device according to (1), in which in the case where the absorption axis of the polarizer and the in-plane slow axis of the λ/2 plate are orthogonal to each other, the Nz factor of the λ/2 plate is 0.15 to 0.35, and

in the case where the absorption axis of the polarizer and the in-plane slow axis of the λ/2 plate are parallel to each other, the Nz factor of the λ/2 plate is 0.65 to 0.85.

(3) The organic electroluminescent display device according to (1) or (2), in which the Nz factor of the λ/4 plate is 0.40 to 0.60.

(4) The organic electroluminescent display device according to any one of (1) to (3), in which the λ/2 plate exhibits reverse wavelength dispersibility.

(5) The organic electroluminescent display device according to any one of (1) to (4), in which the λ/4 plate exhibits reverse wavelength dispersibility.

(6) A circularly polarizing plate comprising, in order: a polarizer; a λ/2 plate; and a λ/4 plate,

in which an angle formed between an absorption axis of the polarizer and an in-plane slow axis of the λ/4 plate is in a range of 20° to 70°,

an Nz factor of the λ4 plate is 0.30 to 0.70,

the absorption axis of the polarizer and an in-plane slow axis of the λ/2 plate are orthogonal or parallel to each other,

in a case where the absorption axis of the polarizer and the in-plane slow axis of the λ/2 plate are orthogonal to each other, an Nz factor of the λ/2 plate is 0.10 to 0.40, and

in a case where the absorption axis of the polarizer and the in-plane slow axis of the λ/2 plate are parallel to each other, the Nz factor of the λ/2 plate is 0.60 to 0.90.

(7) The circularly polarizing plate according to (6), in which in the case where the absorption axis of the polarizer and the in-plane slow axis of the λ/2 plate are orthogonal to each other, the Nz factor of the λ/2 plate is 0.15 to 0.35, and in the case where the absorption axis of the polarizer and the in-plane slow axis of the λ/2 plate are parallel to each other, the Nz factor of the λ/2 plate is 0.65 to 0.85.

(8) The circularly polarizing plate according to (6) or (7), in which the Nz factor of the λ/4 plate is 0.40 to 0.60.

(9) The circularly polarizing plate according to any one of (6) to (8), in which the λ/2 plate exhibits reverse wavelength dispersibility.

(10) The circularly polarizing plate according to any one of (6) to (9), in which the λ/4 plate exhibits reverse wavelength dispersibility.

(11) The circularly polarizing plate according to any one of (6) to (10) that is used for antireflection application.

(12) An organic electroluminescent display device comprising: an organic electroluminescent display panel; and a circularly polarizing plate arranged on the organic electroluminescent display panel,

in which the circularly polarizing plate has a polarizer, a λ/2 plate, λ/4 plate, and a positive C-plate in this order,

an angle formed between an absorption axis of the polarizer and an in-plane slow axis of the λ/4 plate is in a range of 20° to 70°,

a retardation Rth(550) of the positive C-plate in a thickness direction at a wavelength of 550 nm satisfies a relationship of Expression (1) described later,

the absorption axis of the polarizer and an in-plane slow axis of the λ/2 plate are orthogonal or parallel to each other,

in a case where the absorption axis of the polarizer and the in-plane slow axis of the λ/2 plate are orthogonal to each other, an Nz factor of the λ/2 plate is 0.10 to 0.40, and

in a case where the absorption axis of the polarizer and the in-plane slow axis of the λ/2 plate are parallel to each other, the Nz factor of the λ/2 plate is 0.60 to 0.90.

(13) The organic electroluminescent display device according to (12), in which the retardation Rth(550) of the positive C-plate in the thickness direction at a wavelength of 550 nm satisfies a relationship of Expression (2) described later.

(14) The organic electroluminescent display device according to (12) or (13), in which the λ/2 plate exhibits reverse wavelength dispersibility.

(15) The organic electroluminescent display device according to any one of (12) to (14), in which the λ/4 plate exhibits reverse wavelength dispersibility.

(16) A circularly polarizing plate comprising, in order: a polarizer, a λ/2 plate; λ/4 plate; and a positive C-plate,

in which an angle formed between an absorption axis of the polarizer and an in-plane slow axis of the λ/4 plate is in a range of 20° to 70°,

a retardation Rth(550) of the positive C-plate in a thickness direction at a wavelength of 550 nm satisfies a relationship of Expression (1) described later,

the absorption axis of the polarizer and an in-plane slow axis of the λ/2 plate are orthogonal or parallel to each other,

in a case where the absorption axis of the polarizer and the in-plane slow axis of the λ/2 plate are orthogonal to each other, an Nz factor of the λ/2 plate is 0.10 to 0.40, and

in a case where the absorption axis of the polarizer and the in-plane slow axis of the λ/2 plate are parallel to each other, the Nz factor of the λ/2 plate is 0.60 to 0.90.

(17) The circularly polarizing plate according to (16), in which the retardation Rth(550) of the positive C-plate in the thickness direction at a wavelength of 550 nm satisfies a relationship of Expression (2) described later.

(18) The circularly polarizing plate according to (16) or (17), in which the λ/2 plate exhibits reverse wavelength dispersibility.

(19) The circularly polarizing plate according to any one of (16) to (18), in which the λ/4 plate exhibits reverse wavelength dispersibility.

(20) The circularly polarizing plate according to any one of (16) to (19) that is used for antireflection application.

According to the present invention, it is possible to provide a circularly polarizing plate that in the case where the circularly polarizing plate is applied to a display device, further suppresses reflection of external light and a change in tint when viewed in an oblique direction.

According to the present invention, it is also possible to provide an organic EL display device having the circularly polarizing plate.

### BRIEF DESCRIPTION OF THE DRAWINGS

FIG. 1 is a cross-sectional view showing a first embodiment of a circularly polarizing plate according to the present invention.

FIG. 2 is view showing a relationship between an absorption axis of a polarizer, an in-plane slow axis of a λ/2 plate, and an in-plane slow axis of λ/4 plate in the first embodiment of the circularly polarizing plate according to the present invention.

FIG. 3 is a cross-sectional view showing an organic EL display device according to an embodiment of the present invention.

FIG. 4 is a cross-sectional view showing a second embodiment of the circularly polarizing plate according to the present invention.

FIG. 5 is a view showing a relationship between an absorption axis of a polarizer, an in-plane slow axis of a λ/2 plate, and an in-plane slow axis of a λ/4 plate in the second embodiment of the circularly polarizing plate according to the present invention.

FIG. 6 is a cross-sectional view showing a third embodiment of the circularly polarizing plate according to the present invention.

FIG. 7 is a view showing a relationship between an absorption axis of a polarizer, an in-plane slow axis of a λ/2 plate, and an in-plane slow axis of a λ/4 plate in the third embodiment of the circularly polarizing plate according to the present invention.

FIG. 8 is a cross-sectional view showing a fourth embodiment of the circularly polarizing plate according to the present invention.

FIG. 9 is a view showing a relationship between an absorption axis of a polarizer, an in-plane slow axis of a λ/2 plate, and an in-plane slow axis of a λ/4 plate in the fourth embodiment of the circularly polarizing plate according to the present invention.

FIG. 10 is a view for illustrating the order parameters of each axial direction.

### DESCRIPTION OF THE PREFERRED EMBODIMENTS

Hereinafter, the present invention will be described in detail. In present specification, the numerical value range expressed by the term “to” means that the numerical values described before and after “to” are included as a lower limit and an upper limit, respectively. First, the terms used in the present specification will be described.

In the present invention, Re(λ) and Rth(λ) respectively represent an in-plane retardation and a retardation in a thickness direction at a wavelength λ. Unless otherwise specified, the wavelength λ is 550 nm.

In the present invention, Re(λ) and Rth(λ) are values measured at wavelength λ in AxoScan OPMF-1 (manufactured by Opto Science, Inc.). By inputting the average refractive index ((Nx+Ny+Nz)/3) and the film thickness (d (μm)) to AxoScan, the following expressions can be calculated.

Slow axis direction (°)

Re(λ)=R0(λ)

Rth(λ)=((nx+ny)/2−nz)×d

R0(λ) is expressed as a numerical value calculated by AxoScan OPMF-1 but means Re(λ).

In the present specification, the refractive indices nx, ny, and nz are measured using an Abbe refractometer (NAR-4T, manufactured by Atago Co., Ltd.), and a sodium lamp (λ=589 nm) is used as a light source. In addition, in the case where the wavelength dependence is measured, the wavelength dependence can be measured using a combination of a multi-wavelength Abbe refractometer DR-M2 (manufactured by Atago Co., Ltd.) and an interference filter.

In addition, as the refractive index, values described in “Polymer Handbook” (John Wiley&Sons, Inc.) and catalogs of various optical films can also be used. The values of average refractive index of major optical films are as follows: cellulose acylate (1.48), cycloolefin polymer (1.52), polycarbonate (1.59), polymethyl methacrylate (1.49), and polystyrene (1.59).

In the present specification, the Nz factor is a value obtained from Nz=(nx−nz)/(nx−ny).

In the present specification, the term “visible light” refers to light in a wavelength range of 380 to 800 nm.

In the present specification, an angle (for example, an angle of “90°” or the like) and an angular relationship (for example, “orthogonal”, “parallel”, and “crossing at 45°”) include the margin of allowable error in the technical field to which the present invention belongs. For example, the allowable error means that the margin of the error is within a precise angle±10°. A difference between an actual angle and the precise angle is preferably 5° or less and more preferably 3° or less.

In the present specification, the definition of C-plate is as follows.

There are two kinds of C-plates: a positive C-plate and a negative C-plate. The positive C-plate satisfies the relationship of Expression (C1), and the negative C-plate satisfies the relationship of Expression (C2). Rth of the positive C-plate shows a negative value and Rth of the negative C-plate shows a positive value.

nz>nx≅ny Expression (C1)

nz<nx≅ny Expression (C2)

The expression “≅” includes not only a case in which both are completely the same but also a case in which both are substantially the same. Regarding the expression “substantially the same”, for example, “nx≅ny” includes a case in which (nx−ny)×d (wherein d represents a film thickness) is 0 to 10 nm, and preferably 0 to 5 nm.

In the present specification, an “absorption axis” of a polarizer means a direction in which absorbance is maximized. A “transmission axis” means a direction in which an angle with respect to the “absorption axis” is 90°.

In the present specification, an “in-plane slow axis” of each of a λ/2 plate and λ/4 plate means a direction in which a refractive index in a plane is maximized.

### First Embodiment

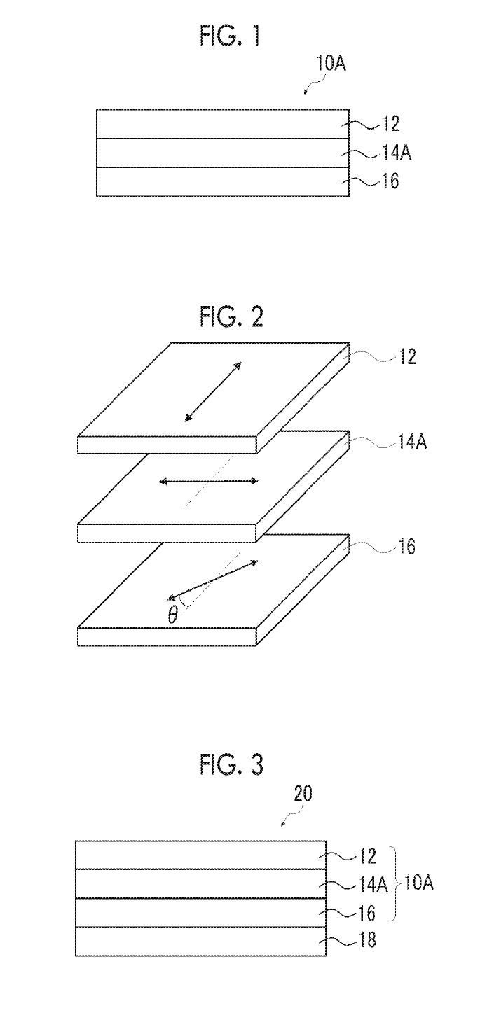

Hereinafter, a first embodiment of a circularly polarizing plate of the present invention will be described with reference to drawings. FIG. 1 is a cross-sectional view showing a first embodiment of a circularly polarizing plate according to the present invention. The drawings in the present invention are schematic and not always identical to actual ones in terms of the thickness relationship and positional relationship of each layer. The same is applied to the following drawings.

A circularly polarizing plate 10A has a polarizer 12, a λ/2 plate 14A, and a λ/4 plate 16 in this order.

In addition, FIG. 2 shows a relationship between an absorption axis of the polarizer 12, an in-plane slow axis of the λ/2 plate 14A, and an in-plane slow axis of the λ/4 plate 16. In FIG. 2, the arrow in the polarizer 12 represents an absorption axis direction, the arrows of the λ/2 plate 14A and the λ/4 plate 16 respectively represent in-plane slow axis directions in the layers.

Hereinafter, each member included in the circularly polarizing plate 10A will be described in detail.

(Polarizer)

The polarizer 12 may be a member having a function of converting light into specific linearly polarized light (linear polarizer) and for example, an absorptive type polarizer may be used.

As the absorptive type polarizer, for example, an iodine-based polarizer, a dye-based polarizer using a dichroic dye, a polyene-based polarizer, and the like may be used. The iodine-based polarizer and the dye-based polarizer include a coating type polarizer and a stretching type polarizer, and any one of these polarizers can be applied. Of these polarizers, a polarizer, which is prepared by allowing polyvinyl alcohol to adsorb iodine or a dichroic dye, and performing stretching, is preferable.

In addition, examples of a method of obtaining a polarizer by performing stretching and dyeing in a state of a laminated film in which a polyvinyl alcohol layer is formed on a base material include methods disclosed in JP5048120B, JP5143918B, JP5048120B, JP4691205B, JP4751481B, and JP4751486B, and known technologies related to these polarizers can be preferably used.

Among these, from the viewpoint of handleability, the polarizer 12 is preferably a polarizer containing a polyvinyl alcohol-based resin (a polymer including —CH₂—CHOH— as a repeating unit, in particular, at least one selected from the group consisting of polyvinyl alcohol and an ethylene-vinyl alcohol copolymer is preferable).

The thickness of the polarizer 12 is not particularly limited but from the viewpoint of achieving excellent handleability and excellent optical properties, the thickness is preferably 35 μm or less, more preferably 3 to 25 μm, and even more preferably 4 to 15 μm. Within the thickness range, an image display device can be made thin.

(λ/2 Plate 14A)

The λ/2 plate 14A is a layer arranged between the polarizer 12 and the λ/4 plate 16 described later. By providing this layer, in a display device including the circularly polarizing plate, reflection of external light and a change in tint are further suppressed in the case where the display device is viewed in an oblique direction.

It is preferable that the λ/2 plate 14A has a single layer structure.

The λ/2 plate 14A refers to an optically anisotropic layer in which the in-plane retardation Re(λ) at a specific wavelength of λ nm satisfies Re(λ)≅λ/2. This expression may be achieved at any wavelength in a visible light range (for example, 550 nm).

In the relationship, from the viewpoint that reflection of external light and/or a change in tint is further suppressed in viewing in an oblique direction in the case where the circularly polarizing plate is applied to a display device (hereinafter, simply referred to as “from the viewpoint that the effect of the present invention is more excellent), the in-plane retardation Re(550) at a wavelength of 550 nm is preferably 200 to 400 nm, more preferably 240 to 320 nm, and even more preferably 250 to 300 nm.

As shown in FIG. 2, the absorption axis of the polarizer 12 and the in-plane slow axis of the λ/2 plate 14A are arranged to be orthogonal to each other.

The term “orthogonal” means that an angle formed between the absorption axis of the polarizer 12 and the in-plane slow axis of the λ/2 plate 14A is 90°±10°, and the formed angle is preferably 85° to 95°, more preferably 88° to 92°, and even more preferably 89° to 91°.

The angle means an angle formed between the absorption axis of the polarizer 12 and the in-plane slow axis of the λ/2 plate 14A in the case of being viewed in a normal direction of the surface of the polarizer 12.

The λ/2 plate 14A may exhibit forward wavelength dispersibility (characteristics in which the in-plane retardation decreases as the measurement wavelength increases) or reverse wavelength dispersibility (characteristics in which the in-plane retardation increases as the measurement wavelength increases), but from the viewpoint that the effect of the present invention is more excellent, it is preferable that the λ/2 plate exhibits reverse wavelength dispersibility. The forward wavelength dispersibility and the reverse wavelength dispersibility are preferably exhibited in the visible light range.

In order to appropriately exhibit the reverse wavelength dispersibility of the in-plane retardation of the λ/2 plate 14A, specifically, the Re(450)/Re(550) of the λ/2 plate 14A is preferably 0.70 or more and less than 1.00, more preferably 0.80 to 0.90, and even more preferably 0.81 to 0.87. The Re(650)/Re(550) of the λ/2 plate 14A is preferably more than 1.00 and 1.20 or less and more preferably 1.04 to 1.18.

The Re(450) and Re(650) represent in-plane retardations of the λ/2 plate 14A measured at wavelengths of 450 nm and 650 nm, respectively.

The Nz factor of the λ/2 plate 14A is 0.10 to 0.40, and from the viewpoint that the effect of the present invention is more excellent, the Nz factor is preferably 0.15 to 0.35, more preferably 0.20 to 0.30, and even more preferably 0.23 to 0.27. The calculation method of the Nz factor is as described above.

Rth(550) which is the retardation of the λ/2 plate 14A in the thickness direction at a wavelength of 550 nm is preferably −120 to −20 nm and more preferably −80 to −50 nm from the viewpoint that the effect of the present invention is more excellent.

It is preferable that the λ/2 plate 14A is formed using a liquid crystal compound. However, as long as predetermined characteristics such as the above-mentioned in-plane retardation are satisfied, the λ/2 plate may be constituted of another material. For example, the λ/2 plate may be formed using a polymer film (particularly, a polymer film subjected to a stretching treatment).

Conventionally, a rigid flat type display panel has been mainly used as an organic EL display panel. However, in recent years, a foldable flexible organic EL display panel has been proposed. For a circularly polarizing plate used for such a flexible organic EL display panel, it is required that the circularly polarizing plate itself is excellent in flexibility. From this viewpoint, since the λ/2 plate 14A formed using a liquid crystal compound is more flexible than a polymer film, the circularly polarizing plate can be suitably applied to a flexible organic EL display panel.

In addition, for the above reason, it is preferable that the λ/4 plate 16 described in detail later is a λ/4 plate formed using a liquid crystal compound.

That is, as long as the circularly polarizing plate includes a λ/2 plate formed using a liquid crystal compound and a λ/4 plate formed using a liquid crystal compound, the circularly polarizing plate can be more suitably applied to a flexible organic EL display panel.

The kind of liquid crystal compound is not particularly limited but, liquid crystal compounds can be classified into a rod-like type (rod-like liquid crystal compound) and a disk-like type (disk-like liquid crystal compound, discotic liquid crystal compound) based on the shape thereof. Further, each kind includes a low molecular type and a high molecular type. A high molecule generally indicates a molecule having a polymerization degree of 100 or more (Masao Doi; Polymer Physics-Phase Transition Dynamics, 1992, IWANAMI SHOTEN, PUBLISHERS, page 2). A mixture of two or more kinds of rod-like liquid crystal compounds, two or more kinds of disk-like liquid crystal compounds, or a rod-like liquid crystal compound and a disk-like liquid crystal compound may be used.

Since changes in temperature and humidity in optical properties can be made small, it is more preferable to form the λ/2 plate 14A using a liquid crystal compound (rod-like liquid crystal compound or disk-like liquid crystal compound) having a polymerizable group. The liquid crystal compound may be a mixed compound of two or more kinds. In this case, it is preferable that at least one has two or more polymerizable groups.

That is, it is preferable that the λ/2 plate 14A is a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer.

The kind of the polymerizable group is not particularly limited and a polymerizable group capable of causing radical polymerization or cationic polymerization is preferable.

A known radically polymerizable group can be used as a radically polymerizable group, and an acryloyl group or a methacryloyl group is preferable.

As a cationically polymerizable group, a known cationically polymerizable group can be used, and specific examples thereof include an alicyclic ether group, a cyclic acetal group, a cyclic lactone group, a cyclic thioether group, a spiro ortho ester group, and a vinyloxy group. Among these, an alicyclic ether group or a vinyloxy group is preferable, and an epoxy group, an oxetanyl group, or a vinyloxy group is more preferable.

Examples of particularly preferable polymerizable groups include the following.

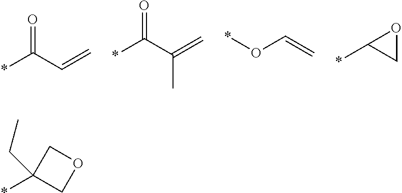

Among these, from the viewpoint that the Nz factor is more easily controlled by a stretching treatment and/or a shrinkage treatment described later, as the liquid crystal compound having the polymerizable group, a compound represented by Formula (I) is preferable.

L₁-G₁-D₁-Ar-D₂-G₂-L₂ Formula (I)

D₁ and D₂ each independently represent —CO—O—, —O—CO—, —C(═S)O—, —O—C(═S)—, —CR¹R²—, —CR¹R²—CR³R⁴—, —O—CR¹R²—, —CR¹R²—O—, —CR¹R²—O—CR³R⁴—, —CR¹R²—O—CO—, —CO—O—CR¹R²—, —CR¹R²—O—CO—CR³R⁴—, —CR¹R²—CO—O—CR³R⁴—, —NR¹—CR²R³—, —CR¹R²—NR³—, —CO—NR¹—, or —NR¹—CO—, and R¹, R², R, and R⁴ each independently represent a hydrogen atom, a halogen atom, or an alkyl group having 1 to 4 carbon atoms.

G₁ and G₂ each independently represent a divalent alicyclic hydrocarbon group having 5 to 8 carbon atoms, a methylene group contained in the alicyclic hydrocarbon group may be substituted by —O—, —S—, or —NR⁶—, and R⁶ represents a hydrogen atom or an alkyl group having 1 to 6 carbon atoms.

L₁ and L₂ each independently represent a monovalent organic group, and at least one selected from the group consisting of L₁ and L₂ represents a monovalent group having a polymerizable group. Among these, it is preferable that one of L₁ and L₂ represents a monovalent group having a polymerizable group and the other represents a monovalent organic group not having a polymerizable group, or one of L₁ and L₂ is a radically polymerizable group and the other is a cationically polymerizable group.

Ar represents a divalent aromatic ring group represented by Formula (II-1), (II-2), (II-3), or (II-4).

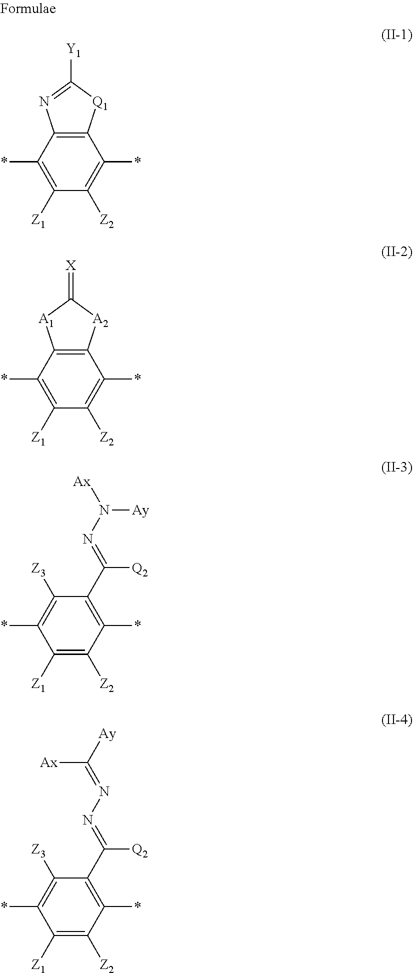

Q₁ represents —S—, —O—, or —NR¹¹—, and R¹¹ represents a hydrogen atom or an alkyl group having 1 to 6 carbon atoms. Y₁ represents an aromatic hydrocarbon group having 6 to 12 carbon atoms or an aromatic heterocyclic group having 3 to 12 carbon atoms. Z₁, Z₂, and Z₃ each independently represent a hydrogen atom, an aliphatic hydrocarbon group having 1 to 20 carbon atoms, an alicyclic hydrocarbon group having 3 to 20 carbon atoms, a monovalent aromatic hydrocarbon group having 6 to 20 carbon atoms, a halogen atom, a cyano group, a nitro group, —NR¹²R¹³, or —SR¹². Z₁ and Z₂ may be bonded to each other to form an aromatic hydrocarbon ring or an aromatic heterocyclic ring, and R¹² and R¹³ each independently represent a hydrogen atom or an alkyl group having 1 to 6 carbon atoms. A₁ and A₂ each independently represent a group selected from the group consisting of —O—, —NR²¹— (R²¹ represents a hydrogen atom or a substituent), —S—, and —CO—. X represents a non-metal atom of Groups XIV to XVI to which a hydrogen atom or a substituent may be bonded. Ax represents an organic group having 2 to 30 carbon atoms and having at least one aromatic ring selected from the group consisting of an aromatic hydrocarbon ring and an aromatic heterocyclic ring. Ay represents a hydrogen atom, an alkyl group having 1 to 6 carbon atoms which may have a substituent, or an organic group having 2 to 30 carbon atoms and having at least one aromatic ring selected from the group consisting of an aromatic hydrocarbon ring and an aromatic heterocyclic ring. The aromatic ring in Ax and Ay may have a substituent, and Ax and Ay may be bonded to each other to form a ring. Q₂ represents a hydrogen atom or an alkyl group having 1 to 6 carbon atoms which may have a substituent.

As for definitions and preferable ranges of the individual substituents of the compound represented by Formula (I), D₁, D₂, G₁, G₂, L₁, L₂, R¹, R², R³, R⁴, Q₁, Y₁, Z₁, and Z₂ of Formula (I) can be referred respectively to the description on D¹, D², G¹, G², L¹, L², R⁴, R⁵, R⁶, R⁷, X¹, Y¹, Q¹, and Q² of Compound (A) in JP2012-021068A, A₁, A₂, and X of Formula (I) can be respectively referred to the description on A₁, A₂, and X of the compound represented by Formula (I) in JP2008-107767A, and Ax, Ay, and Q₂ of Formula (I) can be respectively referred to the description on Ax, Ay, and Q¹ of the compound represented by Formula (I) in WO2013/018526. Z₃ can be referred to the description on Q¹ of Compound (A) in JP2012-021068A.

One of L₁ and L₂ is preferably a group represented by -D₃-G₃-Sp-P₃.

D₃ has the same definition as D₁.

G₃ represents a single bond, a divalent aromatic ring group or heterocyclic group having 6 to 12 carbon atoms, or a divalent alicyclic hydrocarbon group having 5 to 8 carbon atoms, and the methylene group included in the alicyclic hydrocarbon group may be substituted by —O—, —S—, or —NR⁷—, where R⁷ represents a hydrogen atom or an alkyl group having 1 to 6 carbon atoms.

Sp represents a single bond, an alkylene group, —O—, —C(═O)—, —NR⁸—, or a group formed by combining these groups. Examples of the group formed by combining these groups include —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O—(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—NR⁸—(CH₂)ₙ—, —C(═O)—NR⁸—(CH₂)ₙ—O—, —C(═O)—NR⁸—(CH₂—O—)ₙ—, —C(═O)—NR⁸—(CH₂CH₂—O—)ₘ, and —(CH₂)ₙ—O—C(═O)—(CH₂)ₙ—C(═O)—O—(CH₂)ₙ—. Here, n represents an integer of 2 to 12, m represents an integer of 2 to 6, and R⁸ represents a hydrogen atom or an alkyl group having 1 to 6 carbon atoms.

P₃ represents a polymerizable group. The definition of the polymerizable group is as described above.

The other of L₁ and L₂ is preferably a monovalent organic group containing no polymerizable group or a polymerizable group different from P₃. Examples thereof include an aliphatic hydrocarbon group having 1 to 20 carbon atoms, an alicyclic hydrocarbon group having 3 to 20 carbon atoms, and a monovalent aromatic hydrocarbon group having 6 to 20 carbon atoms. The aliphatic hydrocarbon, the alicyclic hydrocarbon group, and the aromatic hydrocarbon group may be substituted by a substituent, and examples of the substituent include an alkyl group.

Generally, an order parameter is known as a parameter indicating the degree of alignment of a liquid crystal compound. The order parameter is 1 in the case where there is no distribution as in a crystal state, and the order parameter is 0 in the case where there is completely random distribution as in a liquid state. For example, a nematic liquid crystal generally has a value of approximately 0.6. The order parameter, for example, is disclosed in detail in “Physical Properties of Liquid Crystal” written by DE JEU, W. H. (Kyoritsu Shuppan Co., Ltd., 1991, Page 11), and is denoted by the following expression.

$$S = \frac{3 〈 {cos}^{2} θ 〉 - 1}{2}$$

Here, θ is an angle formed between an average alignment axis direction of an alignment element (for example, liquid crystal compound) and an axis of each alignment element.

In the present specification, as shown in FIG. 10, in the case where an in-plane slow axis direction of a phase difference plate such as a λ/2 plate or a λ/4 plate is set to an x axis, a direction orthogonal to the slow axis direction in the plane is set to a y axis, a thickness direction of the phase difference plate is set to a z axis, and angles between an average alignment direction M of a mesogenic group derived from the liquid crystal compound obtained by alignment analysis and the x axis, the y axis, and the z axis are set to θ_{X}, θ_{Y}, and θ_{Z}, respectively, an order parameter Sx in the x direction of the mesogenic group, an order parameter Sy in the y direction thereof, and an order parameter Sz in the z direction are respectively expressed by the following expressions.

The mesogenic group is a structure included in the liquid crystal compound and is a functional group which has rigidity and alignment. The structure of the mesogenic group may be, for example, a structure in which a plurality of groups selected from the group consisting of an aromatic ring group and an alicyclic group are linked directly or via a linking group (for example, —CO—, —O—, and —NR— (R represents a hydrogen atom or an alkyl group), or a group formed by combining these groups).

$$Sx = \frac{3 〈 {cos}^{2} θ x 〉 - 1}{2}$$

$$Sy = \frac{3 〈 {cos}^{2} θ y 〉 - 1}{2}$$

$$Sz = \frac{3 〈 {cos}^{2} θ z 〉 - 1}{2}$$

As the method of measuring the order parameter in each direction of the mesogenic group in the phase difference plate, polarization Raman spectrum measurement may be used.

More specifically, as the measurement device, nanofider (manufactured by Tokyo Instruments Inc.) is used in the polarization Raman spectrum measurement. First, the in-plane slow axis (x axis) direction of the phase difference plate is specified using AxoScan OPMF-1 (manufactured by Opto Science, Inc.). Next, the main surface (xy plane) of the phase difference plate, a first cross section (xz plane) of the phase difference plate, and a second cross section (yz plane) of the phase difference plate are set to measurement surfaces, and polarization Raman spectrum measurement is performed. The first cross section and the second cross section are cross sections exposed by cutting the phase difference plate in predetermined directions. The first cross section is a cross section formed by cutting the phase difference plate in a direction parallel to the x axis and perpendicular to the main surface. The second cross section is a cross section formed by cutting the phase difference plate in a direction parallel to the y axis and perpendicular to the main surface.

As a specific method of polarization Raman spectrum measurement, polarization is rotated at several angles at a predetermined excitation wavelength (for example, 785 nm), and polarization Raman spectra in directions parallel and perpendicular to the polarization are measured. Next, according to the method described in Naoki Hayashi, Tatsuhisa Kato, Phys. Rev. E, 63, 021706 (2001), a band with a peak derived from the skeleton of the mesogenic group included in the phase difference plate is subjected to fitting analysis based on the least squares method according to a theoretically derived equation, and secondary order parameters Sxy, Syx, Syz, Szy, Sxz, and Szx in the measurement plane are calculated. Further, the order parameters Sx, Sy, and Sz in the axial directions are calculated based on the following expressions.

Sx=(Sxy+Sxz)/2

Sy=(Syx+Syz)/2

Sz=(Szx+Szy)/2

The structure of the mesogenic group in the phase difference plate can be determined by thermal decomposition gas chromatography-mass spectrometry (GC-MS), infrared (IR) spectrum measurement, and nuclear magnetic resonance (NMR) measurement. In the case where the structure of a liquid crystal compound to be used is known in advance, the structure of the mesogenic group in the phase difference plate can be determined from the structure.

In addition, in the case where the structural site used for alignment analysis of a mesogenic group is parallel to the reference axis of the mesogenic group, the analysis result can be used as it is. In addition, in the case where the structural site used for the alignment analysis of the mesogenic group is orthogonal to the reference axis of the mesogenic group, the analysis result is converted to the direction of the reference axis of the mesogenic group. For example, in the case where a liquid crystal compound in which the structural site used for alignment analysis of the mesogenic group is orthogonal to the reference axis of the mesogenic group exhibits nematic liquid crystallinity, the liquid crystal compound is uniaxially aligned, and thus, by converting the measured values (S_{X⊥}, S_{Y⊥}, S_{Z⊥}) obtained by the above measurement according to Expressions (X) to (Z), the order parameters of the mesogenic group along each axis can be calculated.

The reference axis is an axis for calculating the order parameter, and varies depending on the kind of mesogenic group, which will be described in detail later.

S_{X}=−2S_{X⊥} Expression (X)

S_{Y}=−2S_{Y⊥} Expression (Y)

S_{Z}=−2S_{Z⊥} Expression (Z)

In the case where order parameters are calculated, the reference axis changes depending on the kind of mesogenic group. Specifically, in the case where the mesogenic group is a rod-like mesogenic group, order parameters are calculated based on the major axis of the mesogenic group. That is, the major axis of the mesogenic group serves as a reference axis, the angles formed between the average alignment direction of the major axis of the mesogenic group and the above-mentioned x axis, y axis, and z axis are respectively set to θ_{X}, θ_{Y}, and θ_{Z} so that order parameters are calculated.

In addition, in the case where the mesogenic group is a disk-like mesogenic group, the order parameters are calculated with reference to the axis orthogonal to the disk-like plane of the mesogenic group. That is, the axis orthogonal to the disk-like plane of the mesogenic group is the reference axis, and the angles formed between the average alignment direction of the axis orthogonal to the disk-like plane of the mesogenic group and the above-mentioned x axis, y axis, and z axis are respectively set to θ_{X}, θ_{V}, and θ_{Z} so that order parameters are calculated.

In the λ/2 plate 14A, in the case where the mesogenic group derived from the liquid crystal compound is a rod-like mesogenic group, it is preferable to satisfy the requirements of Expressions (A1) to (A3).

Sx>Sz>Sy Expression (A1)

−0.3<Sz<0.2 (preferably, −0.10<Sz<0.10) Expression (A₂)

Sx>0.05 Expression (A3)

The Sx is preferably 0.1 or more and more preferably 0.2 or more. The upper limit is not particularly limited and is 0.4 or less in many cases.

In addition, Sy is preferably −0.1 or less and more preferably −0.2 or less. The lower limit is not particularly limited and is −0.4 or more in many cases.

Further, a difference between the absolute value of Sx and the absolute value of Sy is preferably 0.1 or less and more preferably 0.04 or less. The lower limit is not particularly limited and is preferably 0.

In the λ/2 plate 14A, in the case where the mesogenic group derived from the liquid crystal compound is a disk-like mesogenic group, the requirements of Expressions (A4) to (A6) are satisfied.

Sy>Sz>Sx Expression (A4)

−0.2<Sz<0.3 (preferably, −0.10<Sz<0.10) Expression (A5)

Sy>0.05 Expression (A6)

The Sx is preferably −0.1 or less and more preferably −0.2 or less. The lower limit is not particularly limited and is −0.4 or more in many cases.

In addition, Sy is preferably 0.1 or more and more preferably 0.2 or more. The upper limit is not particularly limited and is 0.4 or less in many cases.

Further, a difference between the absolute value of Sx and the absolute value of Sy is preferably 0.1 or less and more preferably 0.04 or less. The lower limit is not particularly limited and is preferably 0.

The method of forming the λ/2 plate 14A is not particularly limited and known methods may be used.

Among these, from the viewpoint of easily control the Nz factor, a method of applying a λ/2 plate forming composition including a liquid crystal compound having a polymerizable group (hereinafter, simply referred to as a “polymerizable liquid crystal compound”) (hereinafter, simply referred to as a “composition”) to form a coating film, subjecting the coating film to an alignment treatment to align the polymerizable liquid crystal compound, subjecting the obtained coating film to a curing treatment (ultraviolet irradiation (photoirradiation treatment) or heating treatment), and subjecting the cured film to at least one of a stretching treatment or a shrinkage treatment to obtain a λ/2 plate is preferable.

Hereinafter, the method will be described in detail by dividing the method into steps 1 to 3.

(Step 1)

Step 1 is a step of applying a composition to a support to form a coating film, and subjecting the coating film to an alignment treatment to align a polymerizable liquid crystal compound.

The composition used in the step includes a polymerizable liquid crystal compound. The definition and the preferable range of the polymerizable liquid crystal compound are as described above.

The content of the polymerizable liquid crystal compound in the composition is not particularly limited and from the viewpoint of easily control the Nz factor, the content of the polymerizable liquid crystal compound is preferably 50% by mass or more, more preferably 70% by mass or more, and even more preferably 90% by mass or more with respect to the total solid content of the composition. The upper limit is not particularly limited and is 99% by mass or less in many cases.

The total solid content of the composition does not include a solvent

The composition may include components other than the above-described polymerizable liquid crystal compound.

For example, the composition may include a polymerization initiator. A polymerization initiator to be used is selected according to the kind of polymerization reaction and examples thereof include a thermal polymerization initiator and a photopolymerization initiator. Examples of the photopolymerization initiator include α-carbonyl compounds, acyloin ethers, α-hydrocarbon-substituted aromatic acyloin compounds, polynuclear quinone compounds, and a combination of triarylimidazole dimer and p-aminophenyl ketone.

The content of the polymerization initiator in the composition is preferably 0.01% to 20% by mass and more preferably 0.5% to 5% by mass with respect to the total solid content of the composition.

In addition, the composition may contain a polymerizable monomer from the viewpoint of uniformity of the coating film and hardness of the film.

The polymerizable monomer may be, for example, a radically polymerizable or cationically polymerizable compound. The polymerizable monomer is preferably a polyfunctional radically polymerizable monomer and is more preferably a polymerizable monomer which is copolymerized with the liquid crystal compound having the above-mentioned polymerizable group. Examples of the polymerizable monomer include those described in paragraphs [0018] to [0020] of JP2002-296423A.

The content of the polymerizable monomer in the composition is preferably 1% to 50% by mass and more preferably 2% to 30% by mass with respect to the total mass of the polymerizable liquid crystal compound.

Further, the composition may include a surfactant from the viewpoint of the uniformity of the coating film and the hardness of the film.

Examples of the surfactant include conventionally known compounds, and a fluorine-based compound is preferable. Specific examples of the surfactant include the compounds described in paragraphs [0028] to [0056] of JP2001-330725A and the compounds described in paragraphs [0069] to [0126] of JP2003-295212.

Further, the composition may include a solvent. An organic solvent is preferably used as the solvent. Examples of the organic solvent include an amide (for example, N,N-dimethylformamide), a sulfoxide (for example, dimethyl sulfoxide), a heterocyclic compound (for example, pyridine), a hydrocarbon (for example, benzene or hexane), an alkyl halide (for example, chloroform or dichloromethane), an ester (for example, methyl acetate, ethyl acetate, or butyl acetate), a ketone (for example, acetone or methyl ethyl ketone), and an ether (for example, tetrahydrofuran or 1,2-dimethoxyethane). Among these, an alkyl halide or a ketone is preferable. Two or more kinds of organic solvents may be used in combination.

Further, the composition may contain various alignment controlling agents such as a vertical alignment agent and a horizontal alignment agent. These alignment controlling agents are compounds capable of controlling the alignment of the liquid crystal compound horizontally or vertically on the interface side.

Further, the composition may include other additives such as an adhesion improver, a plasticizer, a polymer or the like in addition to the above-mentioned components.

The support used in Step 1 is a member having a function as a base material for applying the composition. The support may be a temporary support which is peeled off after applying and curing the composition or a temporary support which is peeled off after being stretched.

As the support (temporary support), in addition to a plastic film, a glass substrate or the like may be used. Examples of materials constituting the plastic film include polyesters such as polyethylene terephthalate (PET), polycarbonates, acrylic resins, epoxy resins, polyurethanes, polyamides, polyolefins, cellulose derivatives, silicone, and polyvinyl alcohol (PVA).

The thickness of the support may be about 5 to 1000 μm and is preferably 10 to 250 μm and more preferably 15 to 90 μm.

If necessary, an alignment layer may be arranged on the support.

The alignment layer generally contains a polymer as a main component. Polymers for alignment layers are described in many documents, and many commercial products are available. The polymer to be used is preferably polyvinyl alcohol, polyimide, or a derivative thereof.

The alignment layer is preferably subjected to a known rubbing treatment.

The thickness of the alignment layer is preferably 0.01 to 10 μm and more preferably 0.01 to 1 μm.

Examples of the method for applying the composition include known methods such as a curtain coating method, a dip coating method, a spin coating method, a printing coating method, a spray coating method, a slot coating method, a roll coating method, a slide coating method, a blade coating method, a gravure coating method, and a wire bar method. In the case of performing application using any of the coating methods, single layer coating is preferable.

The coating film formed on the support is subjected to an alignment treatment to align the polymerizable liquid crystal compound in the coating film.

The alignment treatment can be performed by drying the coating film at room temperature or by heating the coating film. In the case of a thermotropic liquid crystal compound, generally, the phase state in the coating film can be transferred to a liquid crystal phase by changing temperature or pressure. In the case of a liquid crystal compound having lyotropic properties, the phase state in the coating film can be transferred to a liquid crystal phase according to the compositional ratio such as the amount of a solvent.

The conditions of the case of heating the coating film are not particularly limited. However, the heating temperature is preferably 50° C. to 150° C. and the heating time is preferably 10 seconds to 5 minutes.

(Step 2)

Step 2 is a step of subjecting the coating film in which the polymerizable liquid crystal compound is aligned to a curing treatment.

The method of the curing treatment performed on the coating film in which the polymerizable liquid crystal compound is aligned is not particularly limited, and examples thereof include a photoirradiation treatment and a heating treatment. Among these, from the viewpoint of production suitability, a photoirradiation treatment is preferable and an ultraviolet irradiation treatment is more preferable.

The irradiation conditions for the photoinadiation treatment are not particularly limited and the irradiation amount is preferably 50 to 1000 mJ/cm².

(Step 3)

Step 3 is a step of subjecting the cured film obtained in Step 2 to at least one of a stretching treatment or a shrinkage treatment to obtain a λ/2 plate. In the step, both a stretching treatment and a shrinkage treatment may be performed, and for example, the kind of treatment may be changed according to the direction such that a stretching treatment is performed in one direction, and a shrinkage treatment is performed in the other direction.

Examples of the method of the stretching treatment include known methods of stretching treatment such as uniaxial stretching and biaxial stretching.

With respect to the shrinkage treatment (particularly, heat shrinkage treatment), methods described in, for example, JP2006-215142A, JP2007-261189A, and JP4228703B can be referred to.

As the above-mentioned support, a support (heat shrinkable support) that shrinks in a specific direction during a heating treatment at the time of stretching may also be mentioned. For example, by using such a support, the cured film can be shrunk in the shrinkage direction of the support while being stretched in a specific direction.

As a direction in which the cured film is subjected to the stretching treatment and/or the shrinkage treatment, the optimum direction is appropriately selected according to the kind of the polymerizable liquid crystal compound to be used and the alignment direction thereof.

For example, in the case where a rod-like liquid crystal compound is used as the polymerizable liquid crystal compound and the polymerizable liquid crystal compound is aligned in the direction perpendicular to the surface of the coating film in Step 1, by stretching the cured film in one direction parallel to the surface (main surface) of the cured film and shrinking the cured film in a direction orthogonal to the one direction in the plane, a λ/2 plate exhibiting a predetermined Nz factor can be obtained.

Although the method of the stretching treatment and the shrinkage treatment has been described above, the present invention is not limited to the above, and the optimum treatment is appropriately performed depending on the kind of liquid crystal compound to be used.

(λ/4 Plate)

The λ/4 plate 16 is a layer arranged on the λ/2 plate 14A.

The λ/4 plate 16 preferably has a single layer structure.

The λ/4 plate (a plate having a λ/4 function) 16 is a plate having a function of converting linearly polarized light having a specific wavelength into circularly polarized light (or circularly polarized light into linearly polarized light). More specifically, the λ/4 plate is a plate of which the in-plane retardation at a predetermined wavelength of λ nm is λ/4 (or odd times thereof).

In the relationship, from the viewpoint that the effect of the present invention is more excellent, the in-plane retardation Re(550) at a wavelength of 550 nm is preferably 100 to 200 nm, more preferably 120 to 160 nm, and even more preferably 130 to 150 nm.

As shown in FIG. 2, the angle θ formed between the absorption axis of the polarizer 12 and the in-plane slow axis of the λ/4 plate 16 is in a range of 20° to 70°. In other words, the angle θ is in a range of 20° to 70°. From the viewpoint that the effect of the present invention is more excellent, the angle θ is preferably 35° to 55°, more preferably 40° to 50°, and even more preferably 43° to 47°.

The angle means an angle formed between the absorption axis of the polarizer 12 and the in-plane slow axis of the λ/4 plate 16 in the case of being viewed in the normal direction of the surface of the polarizer 12.

The λ/4 plate 16 may exhibit forward wavelength dispersibility or reverse wavelength dispersibility in the visible light range. However, from the viewpoint that the effect of the present invention is more excellent, it is preferable that the λ/4 plate exhibits reverse wavelength dispersibility. The wavelength dispersibility is preferably exhibited in the visible light range.

In order to appropriately set the in-plane retardation of the Δ/4 plate 16 to exhibit reverse wavelength dispersibility, specifically, the Re(450)/Re(550) of the λ/4 plate 16 is preferably 0.70 to 1.00, more preferably 0.80 to 0.90, and even more preferably 0.81 to 0.87. The Re(650)/Re(550) of the λ/4 plate 16 is preferably 1.00 to 1.20 and more preferably 1.04 to 1.18.

The Re(450) and the Re(650) represent in-plane retardations of the λ/4 plate 16 measured at wavelengths of 450 nm and 650 nm, respectively.

The Nz factor of the λ/4 plate 16 is 0.30 to 0.70, and from the viewpoint that the effect of the present invention is more excellent, is preferably 0.40 to 0.60 and more preferably 0.45 to 0.55. The method of calculating the Nz factor is as described above.

From the viewpoint that the effect of the present invention is more excellent, Rth(550) which is a retardation of the λ/4 plate 16 in the thickness direction measured at a wavelength of 550 nm is preferably −50 to 50 nm, more preferably −20 to 20 nm, and even more preferably −10 to 10 nm.

The material constituting the λ/4 plate 16 is not particularly limited as long as the above characteristics are exhibited, and the aspects described in the above-mentioned λ/2 plate 14A may be used. Among these, from the viewpoint of easily controlling the above characteristics, the λ/4 plate 16 is preferably a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer.

It is preferable that the order parameters of the mesogenic group derived from the liquid crystal compound in the λ/4 plate 16 satisfy Expressions (A1) to (A3) or Expressions (A4) to (A6) according to the kind of liquid crystal compound.

The method of forming the λ/4 plate 16 is not particularly limited and known methods can be adopted. For example, the above-mentioned method of forming the λ/2 plate 14A may be used.

(Other Layers)

The circularly polarizing plate 10A may include layers other than the polarizer 12, the λ/2 plate 14A, and the λ/4 plate 16 within a range not impairing the effect of the present invention.

For example, the circularly polarizing plate 10A may include an alignment layer having a function of defining the alignment direction of the liquid crystal compound. The position where the alignment layer is arranged is not particularly limited and for example, the alignment layer may be arranged between the polarizer 12 and the λ/2 plate 14A and between the λ/2 plate 14A and the λ/4 plate 16.

The material constituting the alignment layer and the thickness of the alignment layer are as described above.

In addition, the circularly polarizing plate 10A may include an adhesive layer or a pressure sensitive adhesive layer for bonding the respective layers.

Further, a polarizer protective film may be arranged on the surface of the polarizer 12.

The configuration of the polarizer protective film is not particularly limited, and may be, for example, a transparent support or a hardcoat layer, or a laminate of a transparent support and a hardcoat layer.

A known layer can be used as a hardcoat layer and may be, for example, a layer obtained by polymerizing and curing the above-mentioned polyfunctional monomer.

Further, as a transparent support, a known transparent support can be used. For example, as the material for forming the transparent support, a cellulose polymer typified by triacetyl cellulose (hereinafter, referred to as cellulose acylate), a thermoplastic norbornene resin (ZEONEX and ZEONOR manufactured by Zeon Corporation, ARTON manufactured by JSR Corporation, or the like), an acrylic resin, or a polyester resin may be used.

The thickness of the polarizer protective film is not particularly limited and from the viewpoint of being capable of reducing the thickness of the polarizing plate, the thickness is preferably 40 μm or less and more preferably 25 μm or less.

The method of producing the circularly polarizing plate 10A is not particularly limited and for example, a method of laminating a polarizer, a λ/2 plate, and a λ/4 plate respectively prepared through an adhesive or a pressure sensitive adhesive may be used.

The circularly polarizing plate 10A can be applied for various applications, and particularly, can be suitably applied to antireflection application. More specifically, the circularly polarizing plate can be suitably applied to a display device such as an organic EL display device for the antireflection application.

As an aspect of a display device including the circularly polarizing plate 10A, as shown in FIG. 3, an organic EL display device 20 having the circularly polarizing plate 10A and an organic EL display panel 18 in this order from the viewing side indicated by the arrow may be adopted. The polarizer 12 in the circularly polarizing plate 10A is arranged on the viewing side.

The organic EL display panel 18 is a display panel constituted using an organic EL element in which an organic light emitting layer (organic electroluminescent layer) is held between electrodes (between a cathode and an anode).

The configuration of the organic EL display panel is not particularly limited and a known configuration is adopted.

### Second Embodimnent

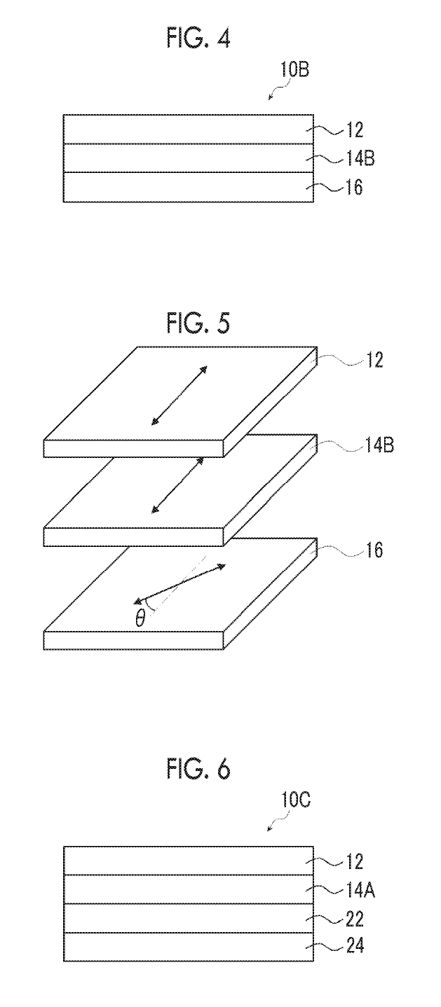

Hereinafter, a second embodiment of the circularly polarizing plate of the present invention will be described with reference to the drawings. FIG. 4 shows a cross-sectional view showing the second embodiment of the circularly polarizing plate of the present invention.

A circularly polarizing plate 10B has a polarizer 12, a λ/2 plate 14B, and a λ/4 plate 16 in this order.

FIG. 5 shows a relationship between an absorption axis of the polarizer 12, an in-plane slow axis of the λ/2 plate 14B, and an in-plane slow axis of the λ/4 plate 16. In FIG. 5, the arrow in the polarizer 12 indicates an absorption axis direction, and the arrows in the layers of the λ/2 plate 14B and the λ/4 plate 16 indicate in-plane slow axis directions, respectively.

The circularly polarizing plate 10B shown in FIG. 4 has the same layers as the circularly polarizing plate 10A shown in FIG. 1 except for the λ/2 plate 14B. Thus, the same constitutional elements are indicated by the same reference numerals and the description thereof is omitted. Hereinafter, the λ/2 plate 14B will be mainly described in detail.

As shown in FIG. 5, the angle θ formed between the absorption axis of the polarizer 12 and the in-plane slow axis of the λ/4 plate 16 is in a range of 20° to 70° as in the first embodiment. A preferable range thereof is as described above. In addition, the circularly polarizing plate 10B may have other layers that the above-mentioned circularly polarizing plate 10A may have.

(λ/2 Plate 14B)

The λ/2 plate 14B is a layer arranged between the polarizer 12 and the λ/4 plate 16 like the λ/2 plate 14A.

The λ/2 plate 14B has the same definition as the above-mentioned λ/2 plate 14A except for the in-plane slow axis direction and the Nz factor. More specifically, the range of the in-plane retardation of the λ/2 plate 14B is the same as the above-mentioned range of the in-plane retardation of the λ/2 plate 14A. In addition, the range of the retardation of the λ/2 plate 14B in the thickness direction is the same as the above-mentioned range of the retardation of the λ/2 plate 14A in the thickness direction. In addition, the λ/2 plate 14B may exhibits forward wavelength dispersibility or reverse wavelength dispersibility and preferably exhibits reverse wavelength dispersibility.

Hereinafter, the in-plane slow axis direction and the Nz factor of the λ/2 plate 14B will be described in detail.

The in-plane slow axis of the λ/2 plate 14B and the absorption axis of the polarizer 12 are arranged to be parallel to each other.

The term “parallel” means that the angle formed between the absorption axis of the polarizer 12 and the in-plane slow axis of the λ/2 plate 14B is 0° to 10°, and the formed angle is preferably 0° to 5°, more preferably 0° to 2°, and even more preferably 0° to 1°.

The angle means an angle formed between the absorption axis of the polarizer 12 and the in-plane slow axis of the λ/2 plate 14B in the case of being viewed in the normal direction of the surface of the polarizer 12.

In addition, the Nz factor of the λ/2 plate 14B is 0.60 to 0.90, and from the viewpoint that the effect of the present invention is more excellent, the Nz factor is preferably 0.65 to 0.85 and more preferably 0.70 to 0.80. The method of calculating the Nz factor is as described above.

The material constituting the λ/2 plate 14B is not particularly limited as long as the above characteristics are exhibited, and the aspects described in the above-mentioned λ/2 plate 14A may be used. Among these, from the viewpoint of easily controlling the above characteristics, the λ/2 plate 14B is preferably a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer. The method of forming the λ/2 plate 14B is not particularly limited and a known method may be adopted. For example, the above-mentioned method of forming the λ/2 plate 14A may be used.

The circularly polarizing plate 10B can be suitably applied for the same application as the above-mentioned circularly polarizing plate 10A. A specific application example is an organic EL display device including the circularly polarizing plate 10B.

### Third Embodiment

Hereinafter, a third embodiment of the circularly polarizing plate of the present invention will be described with reference to the drawings. FIG. 6 shows a cross-sectional view showing the third embodiment of the circularly polarizing plate of the present invention.

A circularly polarizing plate 10C has a polarizer 12, a λ/2 plate 14A, a λ/4 plate 22, and a positive C-plate 24 in this order.

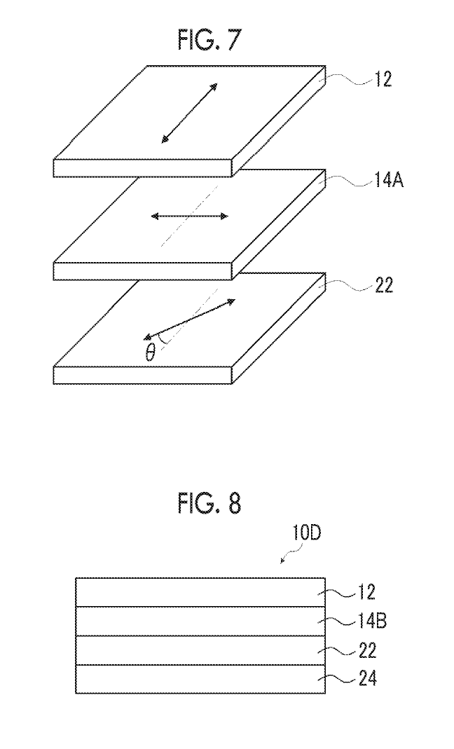

In addition. FIG. 7 shows a relationship between an absorption axis of the polarizer 12, an in-plane slow axis of the λ/2 plate 14A, and an in-plane slow axis of the λ/4 plate 22. In FIG. 7, the arrow in the polarizer 12 indicates an absorption axis direction and the arrows in the respective layers of the λ/2 plate 14A and the λ/4 plate 22 indicate in-plane slow axis directions.

The circularly polarizing plate 10C shown in FIG. 6 has the same layers as the circularly polarizing plate 10A shown in FIG. 1 except for the λ/4 plate 22 and the positive C-plate 24. Thus, the same constitutional elements are indicated by the same reference numerals and the description thereof is omitted. Hereinafter, the λ/4 plate 22 and the positive C-plate 24 will be mainly described in detail.

As shown in FIG. 7, the absorption axis of the polarizer 12 and the in-plane slow axis of the λ/2 plate 14A are arranged to be orthogonal to each other. In addition, the circularly polarizing plate 10C may have other layers that the above-mentioned circularly polarizing plate 10A may have.

(λ/4 Plate 22)

The λ/4 plate (a plate having a λ/4 function) 22 is a plate having a function of converting linearly polarized light having a specific wavelength into circularly polarized light (or circularly polarized light into linearly polarized light). More specifically, the λ/4 plate is a plate of which the in-plane retardation at a predetermined wavelength of λ nm is λ/4 (or odd times thereof).

In the relationship, from the viewpoint that the effect of the present invention is more excellent, the in-plane retardation Re(550) at a wavelength of 550 nm is preferably 100 to 200 nm, more preferably 120 to 160 nm, and even more preferably 130 to 150 nm.

As shown in FIG. 7, the angle θ formed between the absorption axis of the polarizer 12 and the in-plane slow axis of the λ4 plate 22 is in a range of 20° to 70°. In other words, the angle θ is in a range of 20° to 70°. From the viewpoint that the effect of the present invention is more excellent, the angle θ is preferably 35° to 55°, more preferably 40° to 50°, and even more preferably 43° to 47°.

The angle means an angle formed between the absorption axis of the polarizer 12 and the in-plane slow axis of the λ/4 plate 22 in the case of being viewed in the normal direction of the surface of the polarizer 12.

The λ/4 plate 22 may exhibit forward wavelength dispersibility or reverse wavelength dispersibility in the visible light range. However, from the viewpoint that the effect of the present invention is more excellent, the λ/4 plate preferably exhibits reverse wavelength dispersibility. The wavelength dispersibility is preferably exhibited in the visible light range.

In order to appropriately set the in-plane retardation of the λ/4 plate 22 to exhibit reverse wavelength dispersibility, specifically, the Re(450)/Re(550) of the λ/4 plate 22 is preferably 0.70 to 1.00, more preferably 0.80 to 0.90, and even more preferably 0.81 to 0.87. The Re(650)/Re(550) of the λ/4 plate 22 is preferably 1.00 to 1.20 and more preferably 1.04 to 1.18.

The Re(450) and the Re(650) represent in-plane retardations of the λ/4 plate 22 measured at wavelengths of 450 nm and 650 nm, respectively.

From the viewpoint that the effect of the present invention is more excellent, Rth(550) which is a retardation of the λ/4 plate 22 in the thickness direction measured at a wavelength of 550 nm is preferably −50 to 50 nm, more preferably −20 to 20 nm, and even more preferably −10 to 10 nm.

The material constituting the λ/4 plate 22 is not particularly limited as long as the above characteristics are exhibited, and the aspects described in the λ/2 plate 14A in the above-mentioned first embodiment may be used. Among these, from the viewpoint of easily controlling the above characteristics, the λ/4 plate 22 is preferably a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer.

The method of forming the λ/4 plate 22 is not particularly limited and known methods can be adopted. For example, a method including Steps 1 and 2 in the above-mentioned method of forming the λ/2 plate 14A may be used.

(Positive C-Plate 24)

The positive C-plate 24 is a layer arranged on the surface of the λ/4 plate 22 opposite to the polarizer 12 side in the circularly polarizing plate 10C. The positive C-plate 24 preferably has a single layer structure.

Rth(550) which is a retardation of the positive C-plate 24 in the thickness direction at a wavelength of 550 nm satisfies the relationship of Expression (1).

−{(in-plane retardation of the λ/4 plate 22 at a wavelength of 550 nm)×½+30 nm}≤Rth(550)≤−{(in-plane retardation of the λ/4 plate 22 at a wavelength of 550 nm)×½−30 nm} Expression (1)

For example, in the case where the in-plane retardation of the λ/4 plate 22 at a wavelength of 550 nm is 138 nm, Rth(550) which is a retardation of the positive C-plate 24 in the thickness direction at a wavelength of 550 nm is in a range of −99 to −39 μnm.

Among these, from the viewpoint that the effect of the present invention is more excellent, it is preferable to satisfy the relationship of Expression (2).

−{(in-plane retardation of the λ/4 plate 22 at a wavelength of 550 nm)×½+15 nm}≤Rth(550)≤−{(in-plane retardation of the λ/4 plate 22 at a wavelength of 550 nm)×½−15 nm} Expression (2)

From the viewpoint that the effect of the present invention is more excellent, the specific numerical value of Rth(550) is preferably −100 to −50 nm, more preferably −90 to −60 nm, and even more preferably −80 to −60 nm.

The in-plane retardation of the positive C-plate 24 at a wavelength of 550 nm is not particularly limited and from the viewpoint that the effect of the present invention is more excellent, the in-plane retardation is preferably 0 to 10 nm.

The positive C-plate 24 may exhibit forward wavelength dispersibility or reverse wavelength dispersibility, but from the viewpoint that the effect of the present invention is more excellent, it is preferable that the positive C-plate exhibits reverse wavelength dispersibility. The forward wavelength dispersibility and the reverse wavelength dispersibility are preferably exhibited in the visible light range.

The positive C-plate 24 exhibiting forward wavelength dispersibility means that the retardation of the positive C-plate 24 in the thickness direction exhibits forward wavelength dispersibility. That is, this means that as the measurement wavelength increases, the retardation of the positive C-plate 24 in the thickness direction decreases.

In addition, the positive C-plate 24 exhibiting reverse wavelength dispersibility means that the retardation of the positive C-plate 24 in the thickness direction exhibits reverse wavelength dispersibility. That is, this means that as the measurement wavelength increases, the retardation of the positive C-plate 24 in the thickness direction increases.

In order to appropriately set the retardation of the positive C-plate 24 in the thickness direction to exhibit reverse wavelength dispersibility, specifically, the Rth(450)/Rth(550) of the positive C-plate 24 is preferably 0.70 or more and less than 1.00 and more preferably 0.80 to 0.90, and the Rth(650)/Rth(550) of the positive C-plate 24 is preferably more than 1.00 and 1.20 or less and more preferably 1.02 to 1.10.

The Rth(450) and Rth(650) represent retardations of the positive C-plate 24 in the thickness direction measured at wavelengths of 450 nm and 650 nm, respectively.

The thickness of the positive C-plate 24 is not particularly limited and is adjusted such that the retardation in the thickness direction is in a predetermined range. From the viewpoint of reducing the thickness of the phase difference film, the thickness is preferably 6 μm or less, more preferably 0.5 to 5.0 μm, and even more preferably 0.5 to 2.0 μm.

In the present specification, the thickness of the positive C-plate 24 means the average thickness of the positive C-plate 24. The thickness is obtained by measuring the thickness at 5 random points in the positive C-plate 24 and arithmetically averaging those values.

The material constituting the positive C-plate 24 is not particularly limited as long as the above characteristics are exhibited, and the aspects described in the λ/2 plate 14A in the above-mentioned first embodiment may be used. Among these, from the viewpoint of easily controlling the above characteristics, the positive C-plate 24 is preferably a layer formed by fixing a liquid crystal compound (rod-like liquid crystal compound or disk-like liquid crystal compound) having a polymerizable group through polymerization or the like. In this case, after the layer is formed, the liquid crystal compound does not need to exhibit liquid crystallinity any longer.

The method of forming the positive C-plate 24 is not particularly limited and known methods can be adopted. For example, a method including Steps 1 and 2 in the above-mentioned method of forming the λ/2 plate 14A may be used.

It is preferable that at least one of the λ/2 plate 14A, the λ/4 plate 22, or the positive C-plate 24 exhibits reverse wavelength dispersibility, and it is more preferable that all of the λ/2 plate, the λ/4 plate, or the positive C-plate exhibit reverse wavelength dispersibility.

The circularly polarizing plate 10C can be suitably applied for the same application as the above-mentioned circularly polarizing plate 10A. A specific application example is an organic EL display device including the circularly polarizing plate 10C.

### Fourth Embodiment

Hereinafter, a fourth embodiment of the circularly polarizing plate according to the present invention will be described with reference to the drawings. FIG. 8 shows a cross-sectional view showing the fourth embodiment of the circularly polarizing plate according to the present invention.

A circularly polarizing plate 10D has a polarizer 12, a λ/2 plate 14B, a λ/4 plate 22, and a positive C-plate 24 in this order.

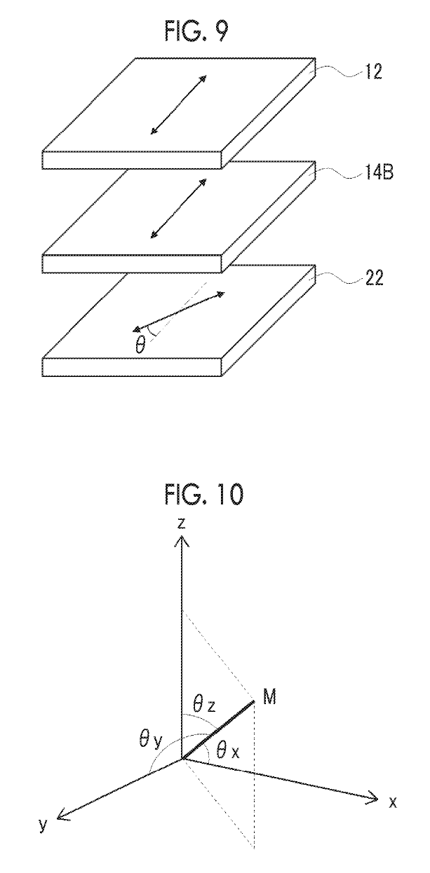

FIG. 9 shows a relationship between an absorption axis of the polarizer 12, an in-plane slow axis of the λ/2 plate 14B, and an in-plane slow axis of the λ/4 plate 22. In FIG. 9, the arrow in the polarizer 12 indicates an absorption axis direction and the arrows in the respective layers of the λ/2 plate 14B and the λ/4 plate 22 indicate in-plane slow axis directions.

The circularly polarizing plate 10D shown in FIG. 8 has the same layers as the circularly polarizing plate 10C shown in FIG. 6 except the λ/2 plate 14B. Thus, the same constitutional elements are indicated by the same reference numerals and the description thereof is omitted.

In addition, the aspect of the λ/2 plate 14B in the circularly polarizing plate 10D shown in FIG. 8 is the same as the aspect described in the above-mentioned second embodiment, and the description thereof is omitted.

As shown in FIG. 9, the in-plane slow axis of the λ/2 plate 14B and the absorption axis of the polarizer 12 are arranged to be parallel to each other. In addition, the angle θ formed between the absorption axis of the polarizer 12 and the in-plane slow axis of the λ/4 plate 22 is in a range of 20° to 70° as in the first embodiment. A preferable range thereof is as described above. In addition, the circularly polarizing plate 10D may have other layers that the above-mentioned circularly polarizing plate 10A may have.

The circularly polarizing plate 10D can be suitably applied for the same application as the above-mentioned circularly polarizing plate 10A. A specific application example is an organic EL display device including the circularly polarizing plate 10D.

### EXAMPLES

The features of the present invention will be described in more detail with reference to the following Examples. The materials, the amount of the materials used, the ratio between the materials, the content and the procedures of treatment, and the like shown in the following examples can be appropriately modified as long as the modification does not depart from the gist of the present invention. Accordingly, the scope of the present invention is not limited to the following specific examples.

### Example 1

<<Preparation of Polarizer>>

<Preparation of Protective Film>

The following composition was put into a mixing tank and was stirred to dissolve the respective components, thereby preparing a core layer cellulose acylate dope.

| | |
|---|---|
| Cellulose acetate having an acetyl substitution degree | 100 parts by mass |
| of 2.88 | |
| Ester oligomer (Compound 1-1) | 10 parts by mass |
| Durability improver (Compound 1-2) | 4 parts by mass |
| Ultraviolet absorbing agent (Compound 1-3) | 3 parts by mass |
| Methylene chloride (first solvent) | 438 parts by mass |
| Methanol (second solvent) | 65 parts by mass |

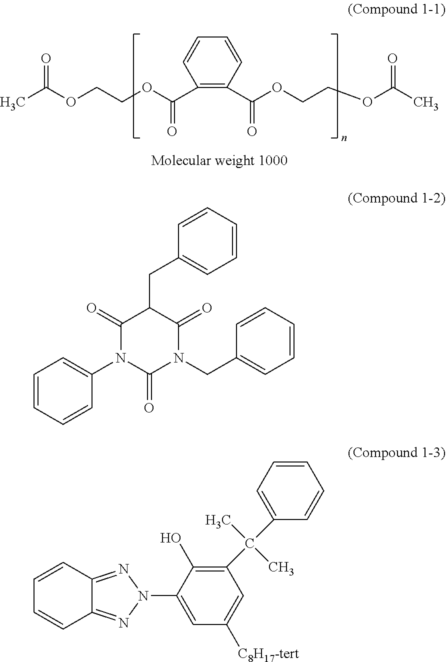

[Preparation of Outer Layer Cellulose Acylate Dope]

10 parts by mass of a matting agent dispersion liquid having the following composition was added to 90 parts by mass of the above-mentioned core layer cellulose acylate dope to prepare an outer layer cellulose acylate dope.

| | |
|---|---|
| Silica particles having an average particle size of | 2 parts by mass |
| 20 nm (AEROSIL R972, manufactured by Nippon | |
| Aerosil Co., Ltd.) | |
| Methylene chloride (first solvent) | 76 parts by mass |
| Methanol (second solvent) | 11 parts by mass |
| Core layer cellulose acylate dope 1 | 1 part by mass |

[Preparation of Cellulose Acylate Film]

Three layers of the core layer cellulose acylate dope and the outer layer cellulose acylate dopes on both sides thereof were cast simultaneously onto a drum at 20° C. from a casting port. The film was peeled from the drum in a state where the solvent content of the film was approximately 20% by mass, and both ends in the width direction of the peeled film were fixed with tenter clips. Then, the film was dried while stretching the film 1.2 times in the transverse direction in a state where the residual solvent was 3% to 15% by mass. Thereafter, the stretched film was conveyed between the rolls of a heat treatment apparatus to prepare a cellulose acylate film having a thickness of 25 μm. The film was used as a polarizing plate protective film.

<Preparation of Hardcoat Layer>

As a hardcoat layer forming coating liquid, a curable composition for hardcoat in Table 1 below was prepared.

TABLE 1

| | Monomer | | | | UV Initiator | | |
|---|---|---|---|---|---|---|---|
| | | | Monomer | Total amount added | | Amount added | |
| | Monomer 1 | Monomer 2 | 1/Monomer 2 | [parts by mass] | Kind | [parts by mass] | Solvent |
| Hardcoat 1 | Pentaerythritol | Pentaerythritol | 3/2 | 53.5 | UV initiator 1 | 1.5 | Ethyl |
| | triacrylate | tetraacrylate | | | | | acetate |

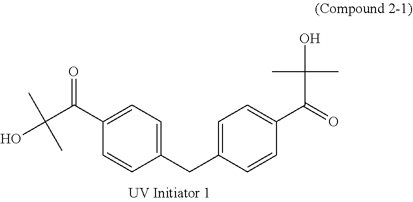 [SMILES: CC(C)(O)C(=O)c1ccc(Cc2ccc(C(=O)C(C)(C)O)cc2)cc1]

The curable composition for hardcoat was applied onto the surface of the polarizing plate protective film prepared above. Thereafter, the coating film of the polarizing plate protective film was dried at 100° C. for 60 seconds, and the coating film was cured with irradiation of ultraviolet (UV) light at 1.5 kW and at 300 mJ under the conditions of nitrogen of 0.1% or less, thereby preparing a protective film with a hardcoat layer which has a hardcoat layer with a thickness of 3 μm. The film thickness of the hardcoat layer was adjusted by adjusting the coating amount in a die coating method using a slot die.

<Preparation of Polarizing Plate with Protective Film on One Surface>

1) Saponification of Film

The protective film with a hardcoat layer thus prepared was immersed in a 4.5 mol/L sodium hydroxide aqueous solution (saponification solution) whose temperature was adjusted to 37° C. for 1 minute. Thereafter, the protective film with a hardcoat layer was taken out and was washed with water. Then, the protective film with a hardcoat layer was immersed in a 0.05 mol/L sulfuric acid aqueous solution for 30 seconds, and then the protective film with a hardcoat layer was taken out and further caused to pass through a water washing bath. Then, the obtained film was dewatered repeatedly three times with an air knife to remove water, and then dried by retaining in a drying zone at 70° C. for 15 seconds, thereby preparing a saponified protective film with a hardcoat layer.

2) Preparation of Polarizer

The film was stretched in the longitudinal direction with two pairs of nip rolls having a difference in circumferential speed according to Example 1 of JP2001-141926A under changed drying conditions, thereby preparing a polarizer having a width of 1330 mm and a thickness of 15 μm.

3) Lamination

The prepared polarizer and the saponified protective film with a hardcoat layer were laminated by a roll-to-roll process using a 3 mass % aqueous solution of PVA (PVA-117H, manufactured by Kuraray Co., Ltd.) as an adhesive in such a manner that the absorption axis of the polarizer and the longitudinal direction of the film were arranged to be parallel to each other (protective film with a hardcoat layer), and thus a polarizer with a protective film on one surface was prepared.

At this time, the cellulose acylate film side of the protective film with a hardcoat layer was laminated to be arranged on the polarizer side.

<<Preparation of λ/2 Plate>>

<Preparation of Temporary Support>

A pellet of a mixture (Tg 127° C.) of 90 parts by mass of an acrylic resin having a lactone ring structure represented by Formula (II) {copolymerization monomer mass ratio=methyl methacrylate/methyl 2-(hydroxymethyl) acrylate=8/2, lactone cyclization ratio: about 100%, content ratio of the lactone ring structure:19.4%, weight-average molecular weight:133,000, melt flow rate: 6.5 g/10 min (240° C., 10 kgf), Tg 131° C.}, and 10 parts by mass of acrylonitrile-styrene (AS) resin {Toyo AS AS20, manufactured by Toyo-Styrene Co., Ltd.}; was supplied to a twin-screw extruder and melt-extruded in a sheet form at about 280° C. Thereafter, the melt-extruded sheet was longitudinally stretched in a longitudinal uniaxial stretching machine at an aeration temperature of 130° C., a sheet surface temperature of 120° C., a stretching rate of 30%/min, and a stretching ratio of 35%. Then, the longitudinally stretched sheet was transversely stretched at using a tenter type stretching machine, at an aeration temperature of 130° C., a sheet surface temperature of 120° C., a stretching rate of 30%/min, and a stretching ratio of 35%. Then, both ends of the transversely stretched sheet were cut off before the winding section and the sheet was wound up as a roll film having a length of 4000 m. Thus, a long temporary support having a thickness of 40 μm was obtained.

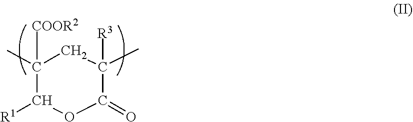

In Formula (II), R¹ represents a hydrogen atom and R² and R³ represent a methyl group.

<Formation of Alignment Layer>

An alignment layer coating liquid (A) having the following composition was continuously applied to the temporary support using a #14 wire bar. The temporary support coated with the alignment layer coating liquid was dried with warm air at 60° C. for 60 seconds and further dried with warm air at 100° C. for 120 seconds, thereby forming an alignment layer on the temporary support.

The saponification degree of modified polyvinyl alcohol used was 96.8%.

-Composition of Alignment Layer Coating Liquid (A)-

| | |
|---|---|
| Modified polyvinyl alcohol below | 10 parts by mass |
| Water | 308 parts by mass |
| Methanol | 70 parts by mass |
| Isopropanol | 29 parts by mass |
| Photopolymerization initiator (IRGACURE | 0.8 parts by mass |
| (registered trademark) 2959, manufactured by BASF | |
| SE) | |

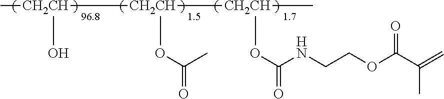

Modified Polyvinyl Alcohol

The compositional ratio of modified polyvinyl alcohol is described by a mole fraction.

<Formation of Liquid Crystal Layer>

Next, the formation of a liquid crystal layer in which a rod-like liquid crystal compound is vertically aligned and fixed in a nematic phase will be described.

A composition 1 shown in Table 2 described later was dissolved in methyl ethyl ketone (MEK) to perform preparation such that the concentration of solid contents was 10% by mass. Thus, a coating liquid was obtained. The obtained coating liquid was applied to the alignment layer using a bar coater and heated and aged at 120° C. for 2 minutes. Thus, a homogeneous alignment state of the rod-like liquid crystal compound in the coating film was obtained. Then, the coating film was kept at 120° C. and was irradiated with ultraviolet rays at 100 mJ/cm² using a metal halide lamp at 120° C. to form a liquid crystal layer (film thickness: 17 μm).

<Deformation>

The film including the temporary support and the liquid crystal layer prepared as described above was deformed in a batch type stretching machine with four sides fixed with tenter clips at an aeration temperature of 140° C., a film surface temperature of 130° C., and a deformation rate of 30%/min, so as to have a deformation rate shown in Table 3 (X direction: 75% stretched, Y direction: 10% shrunk). Then, the end portions of the four sides of the obtained film were cut off and thus a stretched film A including a temporary support and a λ/2 plate was obtained.

The X direction means the in-plane slow axis direction and the Y direction means a direction orthogonal to the X direction in the plane. The same applies to Examples and Comparative Examples described later.

<<Preparation (A) of λ/4 Plate>>

A temporary support with an alignment layer was produced according to the method described in the above <<Preparation of λ/2 Plate>>.

<Formation of Liquid Crystal Layer>

Next, the formation of a liquid crystal layer in which the rod-like liquid crystal compound is vertically aligned and fixed in a nematic phase will be described.

The composition 1 shown in Table 2 described later was dissolved in MEK to perform preparation such that the concentration of solid contents was 10% by mass. Thus, a coating liquid was obtained. The obtained coating liquid was applied to the alignment layer using a bar coater and heated and aged at 120° C. for 2 minutes. Thus, a homogeneous alignment state of the rod-like liquid crystal compound in the coating film was obtained. Then, the coating film was kept at 120° C. and was irradiated with ultraviolet rays at 100 mJ/cm² at 120° C. using a metal halide lamp to form a liquid crystal layer (film thickness: 8 μm).

<Deformation>

The film including the temporary support and the liquid crystal layer prepared as described above was deformed in a batch type stretching machine with four sides fixed with tenter clips at an aeration temperature of 140° C., a film surface temperature of 130° C., and a deformation rate of 30%/min, so as to have a deformation rate shown in Table 3 (X direction: 80% stretched, Y direction: 10% shrunk). Then, the end portions of the four sides of the obtained film were cut off and thus a stretched film B including a temporary support and a λ/4 plate was obtained.

<<Preparation of Circularly Polarizing Plate>>

The polarizer with a protective film on one surface and the film A were laminated on the polarizer side surface of the obtained polarizer with a protective film on one surface through a commercially available acrylic adhesive (UV-3300 manufactured by Toagosei Co., Ltd.) such that the polarizer faced the λ/2 plate, and thus a laminate was obtained. The laminate was irradiated with ultraviolet rays at an irradiation amount of 100 mJ/cm² from the temporary support side using a metal halide lamp to cure the adhesive. Then, the stretched temporary support was peeled off from the obtained film.

Next, the film and the film B were laminated on the λ/2 plate side surface of the film including the polarizer with a protective film on one surface and the λ/2 plate through a commercially available acrylic adhesive (UV-3300 manufactured by Toagosei Co., Ltd.) such that the λ/2 plate faced the λ/4 plate, and thus a laminate was obtained. The laminate was irradiated with ultraviolet rays at an irradiation amount of 100 mJ/cm² from the temporary support side using a metal halide lamp to cure the adhesive. Then, the stretched temporary support was peeled off from the obtained film to prepare a circularly polarizing plate having a polarizer, a λ/2 plate, and a λ/4 plate in this order.

Each layer was laminated so as to have angles shown in “Angle (°) formed between in-plane slow axis of λ/2 plate and absorption axis of polarizer” and “Angle (°) formed between in-plane slow axis of λ/4 plate and absorption axis of polarizer” shown in Table 3 described later.

### Examples 2 to 11 and Comparative Examples 1 to 3

Circularly polarizing plates were prepared according to the same procedure as in Example 1 except that in the <<Preparation of λ/2 Plate>> and <<Preparation (A) of λ/4 Plate>>, the kind of composition, the thickness of the liquid crystal layer, the deformation rate, and the angle (°) formed between the in-plane slow axis of the λ/2 plate and the absorption axis of the polarizer were changed as shown in Table 3 described later.

The stretched temporary support was peeled off from each of the films A and B, and the Re(λ), Rth(λ), the slow axis direction of the λ/2 plate and the λ/4 plate were measured using AxoScan, and further, the Nz factor was calculated.

The compositions of compositions 1 to 5 are summarized in Table 2.

Each numerical value in Table 2 is expressed in “parts by mass”.

TABLE 2

| | Composition 1 | Composition 2 | Composition 3 | Composition 4 | Composition 5 |
|---|---|---|---|---|---|
| Rod-like liquid crystal compound (1) | 70 | 40 | | 70 | 40 |
| Rod-like liquid crystal compound (2) | 30 | | | 30 | |
| Rod-like liquid crystal compound (3) | | 60 | | | 60 |
| Disk-like liquid crystal compound 101 | | | 80 | | |
| Disk-like liquid crystal compound 102 | | | 20 | | |
| Polymerization initiator 1 | 1.5 | 1.5 | 1.5 | 1.5 | 1.5 |
| Polymerization initiator 2 | 1.5 | 1.5 | 1.5 | 1.5 | 1.5 |
| Vertical alignment agent 1 | 0.5 | 0.5 | | | |
| Vertical alignment agent 2 | | | 2 | | |
| Polymerizable compound 1 | 0.5 | | 0.5 | | |
| Polymerizable compound 2 | | 10 | | | 10 |
| HISOLVE MTEM | | | | 2 | 2 |
| NK ESTER A-200 | | | | 1 | 1 |
| Surfactant 1 | 0.2 | 0.2 | 0.2 | | |
| Surfactant 2 | 0.4 | 0.4 | 0.4 | | |
| Surfactant 3 | | | | 0.2 | 0.2 |

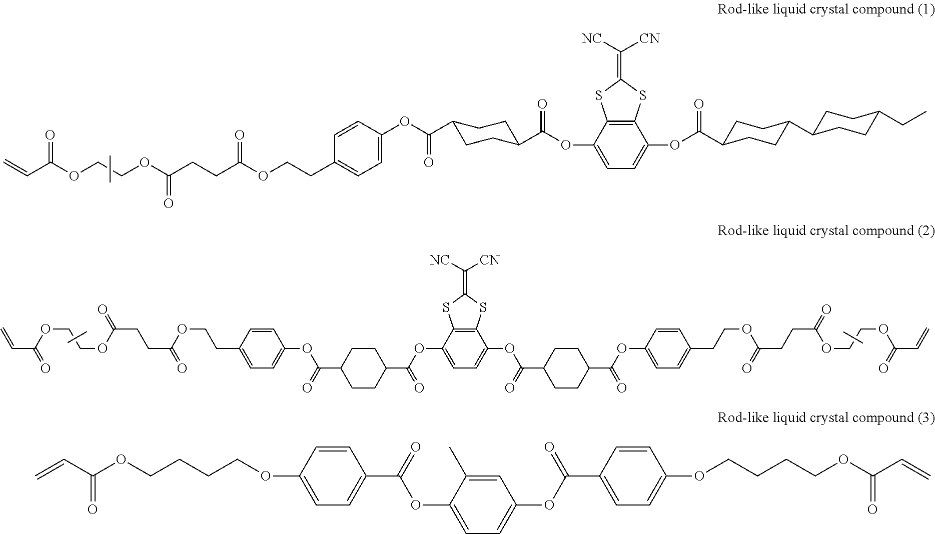

Disk-like liquid crystal compound

| | |
|---|---|
| 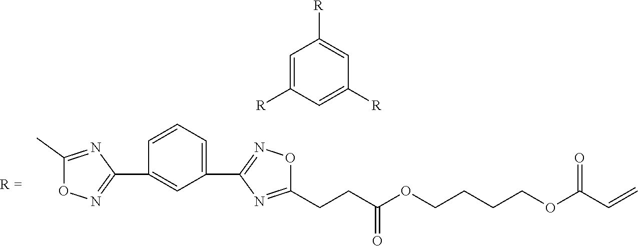 | Compound 101 |
| 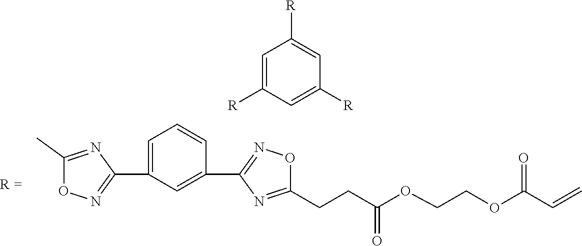 | Compound 102 |

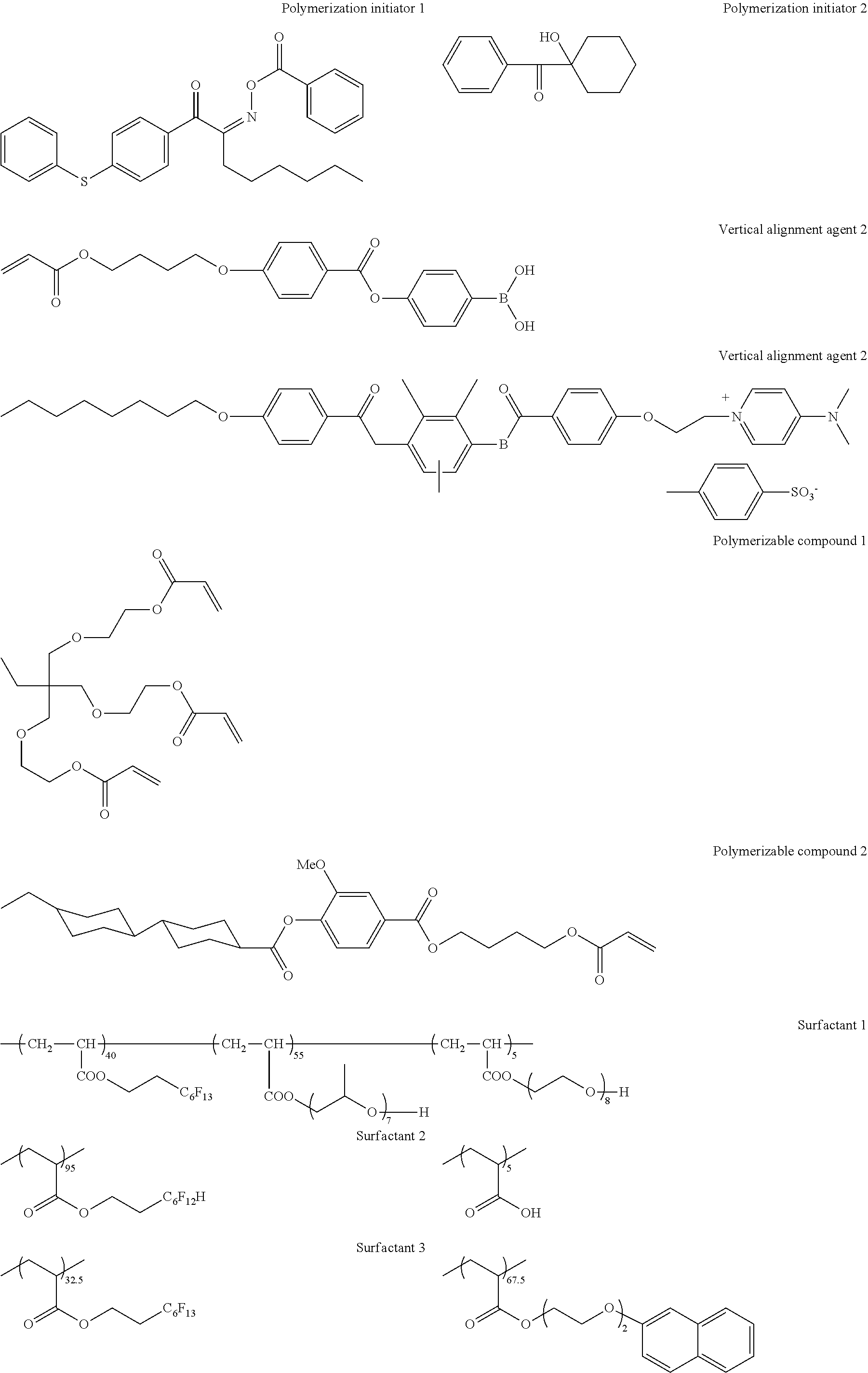

[Mounting of Circularly Polarizing Plate on Organic EL Display Panel and Evaluation of Display Performance]

(Mounting of Circularly Polarizing Plate on Organic EL Display Device)

GALAXY S IV manufactured by SAMSUNG Co., Ltd. equipped with an organic EL display panel was decomposed, the circularly polarizing plate was peeled off, and each of the circularly polarizing plates of Examples 1 to 11 and Comparative Examples 1 to 3 was laminated on the organic EL display panel to prepare an organic EL display device.

(Evaluation of Display Performance)

The reflectivity and reflection tint of the prepared organic EL display device were evaluated under light conditions. In a black display where external light reflected light is most easily visible, the reflected light when fluorescent light was projected from a polar angle of 45° was observed. Specifically, the reflected light in the viewing angle direction (polar angle 45°, azimuthal angle 0° to 165° in 15° increments) was measured with a spectroradiometer SR-3 (manufactured by Topcon Corporation) and evaluation was performed based on the following standards using Comparative Example 1 as a reference.

(Reflectivity)

A: A case where the ratio of the maximum brightness of reflected light with respect to the maximum brightness of reflected light in Comparative Example 1 is 40% or less.

B: A case where the ratio of the maximum brightness of reflected light with respect to the maximum brightness of reflected light in Comparative Example 1 is more than 40% and 60% or less.

C: A case where the ratio of the maximum brightness of reflected light with respect to the maximum brightness of reflected light in Comparative Example 1 is more than 60% and 80% or less.

D: A case where the ratio of the maximum brightness of reflected light with respect to the maximum brightness of reflected light in Comparative Example 1 is more than 80%.

(Change in Tint)

For a change in tint (change in reflection tint), the magnitude Δa*b* of change in tint a* and b* of reflected light at all measurement angles was defined by the following expression.

$$Δ {a}^{*} {b}^{*} = \sqrt{{( M aximum {a}^{*} - Minimum {a}^{*} )}^{2} + {( M aximum {b}^{*} - Minimum {b}^{*} )}^{2}}$$

A: A case where the ratio of a change in reflection tint of reflected light with respect to a change in reflection tint of reflected light in Comparative Example 1 is 40% or less.

B: A case where the ratio of a change in reflection tint of reflected light with respect to a change in reflection tint of reflected light in Comparative Example 1 is more than 40% and 60% or less.

C: A case where the ratio of a change in reflection tint of reflected light with respect to a change in reflection tint of reflected light in Comparative Example 1 is more than 60% and 80% or less.

D: A case where the ratio of a change in reflection tint of reflected light with respect to a change in reflection tint of reflected light in Comparative Example 1 is more than 80%.

In Table 3, the Re(550), Rth(550), Nz, Re(450)/Re(550), and Re(650)/Re(550) of the obtained λ/2 plate and λ/4 plate are shown.

In Table 3, in the column of “Preparation conditions of λ/2 plate”, the kind of liquid crystal composition used, the film thickness of the liquid crystal layer, the deformation rate in the X direction (X deformation rate), and the Y direction deformation rate (Y deformation rate) are respectively shown. In addition, in the X deformation rate column and the Y deformation rate column, the minus notation means shrinkage, and the plus notation means stretching.

TABLE 3

| | | | | | | | | | | | | | Comparative | Comparative | Comparative |
|---|---|---|---|---|---|---|---|---|---|---|---|---|---|---|---|
| | | Example 1 | Example 2 | Example 3 | Example 4 | Example 5 | Example 6 | Example 7 | Example 8 | Example 9 | Example 10 | Example 11 | Example 1 | Example 2 | Example 3 |
| λ/2 Plate | Re(550) (nm) | 275 | 275 | 275 | 275 | 275 | 275 | 275 | 275 | 275 | 275 | 275 | 275 | 275 | 275 |
| | Rth(550) (nm) | −69 | −83 | −41 | −107 | −39 | −69 | −69 | −69 | 69 | 30 | 102 | −138 | 138 | 138 |
| | Nz | 0.25 | 0.2 | 0.35 | 0.11 | 0.39 | 0.25 | 0.25 | 0.25 | 0.75 | 0.61 | 0.87 | 0 | 1 | 1 |
| | Re(450)/Re(550) | 0.85 | 0.85 | 0.85 | 0.85 | 0.85 | 0.85 | 0.85 | 1.09 | 0.85 | 0.85 | 0.85 | 1.09 | 0.85 | 1.09 |
| | Re(650)/Re(550) | 1.05 | 1.05 | 1.05 | 1.05 | 1.05 | 1.05 | 1.05 | 0.96 | 1.05 | 1.05 | 1.05 | 0.96 | 1.05 | 0.96 |
| | Angle (°) formed | 90 | 90 | 90 | 90 | 90 | 90 | 90 | 90 | 0 | 0 | 0 | 90 | 0 | 0 |
| | between in-plane slow | | | | | | | | | | | | | | |
| | axis of λ/2 plate and | | | | | | | | | | | | | | |
| | absorption axis | | | | | | | | | | | | | | |
| | of polarizer | | | | | | | | | | | | | | |
| Preparation | Liquid crystal | Compo- | Compo- | Compo- | Compo- | Compo- | Compo- | Compo- | Compo- | Compo- | Compo- | Compo- | Compo- | Compo- | Compo- |
| conditions | composition | sition 1 | sition 1 | sition 1 | sition 1 | sition 1 | sition 1 | sition 1 | sition 2 | sition 1 | sition 1 | sition 1 | sition 3 | sition 4 | sition 5 |
| of λ/2 plate | Film thickness of | 17 | 17.5 | 16.5 | 18 | 16.2 | 17 | 17 | .5 | 16 | 16.1 | 15.5 | 5 | 5 | 5 |
| | liquid crystal layer (μm) | | | | | | | | | | | | | | |
| | X deformation rate (%) | 75 | 75 | 77 | 70 | 79 | 75 | 75 | 75 | 85 | 82 | 88 | 0 | 0 | 0 |
| | Y deformation rate (%) | −10 | −8 | −10 | −8 | −10 | −10 | −10 | −10 | −10 | −10 | −10 | 0 | 0 | 0 |
| λ/4 Plate | Re(550) (nm) | 138 | 138 | 138 | 138 | 138 | 138 | 138 | 138 | 138 | 138 | 138 | 138 | 138 | 138 |
| | Rth(550) (nm) | 0 | 0 | 0 | 0 | 0 | −14 | 25 | 0 | 0 | 0 | 0 | 0 | 0 | 0 |
| | Nz | 0.5 | 0.5 | 0.5 | 0.5 | 0.5 | 0.4 | 0.68 | 0.5 | 0.5 | 0.5 | 0.5 | 0.5 | 0.5 | 0.5 |
| | Re(450)/Re(550) | 0.85 | 0.85 | 0.85 | 0.85 | 0.85 | 0.85 | 0.85 | 0.85 | 0.85 | 0.85 | 0.85 | 0.85 | 0.85 | 0.85 |
| | Re(650)/Re(550) | 1.05 | 1.05 | 1.05 | 1.05 | 1.05 | 1.05 | 1.05 | 1.05 | 1.05 | 1.05 | 1.05 | 1.05 | 1.05 | 1.05 |
| | Angle (°) formed | 45 | 45 | 45 | 45 | 45 | 45 | 45 | 45 | 45 | 45 | 45 | 45 | 45 | 45 |
| | between in-plane slow | | | | | | | | | | | | | | |
| | axis of λ/4 plate and | | | | | | | | | | | | | | |
| | absorption axis | | | | | | | | | | | | | | |
| | of polarizer | | | | | | | | | | | | | | |
| Preparation | Liquid crystal | Compo- | Compo- | Compo- | Compo- | Compo- | Compo- | Compo- | Compo- | Compo- | Compo- | Compo- | Compo- | Compo- | Compo- |
| conditions | composition | sition 1 | sition 1 | sition 1 | sition 1 | sition 1 | sition 1 | sition 1 | sition 1 | sition 1 | sition 1 | sition 1 | sition 1 | sition 1 | sition 1 |
| of λ/4 plate | Film thickness of | 8 | 8 | 8 | 8 | 8 | 8.2 | 8 | 8 | 8 | 8 | 8 | 8 | 8 | 8 |
| | liquid crystal layer (μm) | | | | | | | | | | | | | | |
| | X deformation rate (%) | 80 | 80 | 80 | 80 | 80 | 75 | 88 | 80 | 80 | 80 | 80 | 80 | 80 | 80 |
| | Y deformation rate (%) | −10 | −10 | −10 | −10 | −10 | −10 | −10 | −10 | −10 | −10 | −10 | −10 | −10 | −10 |
| Display | Reflectivity | A | A | B | C | C | B | C | B | A | C | C | D | D | D |
| performance | Change in tint | A | A | A | B | B | B | C | C | A | B | B | D | C | D |

As shown in Table 3, in the case of using the circularly polarizing plate satisfying a predetermined Nz factor relationship, it was confirmed that the desired effect could be obtained.

Among examples, as understood from the comparison of Examples 1 to 5, it was confirmed that in the case where the Nz factor of the λ/2 plate was 0.15 to 0.35, the effect was more excellent and in the case where the Nz factor was 0.20 to 0.30, the effect was even more excellent.

In addition, as understood from the comparison of Examples 1, 6, and 7, it was confirmed that the effect was more excellent in the case where the Nz factor of the λ/4 plate was 0.40 to 0.60, and the effect was even more excellent in the case where the Nz factor was 0.45 to 0.55.

Further, from the comparison of Examples 1 and 8, it was confirmed that the effect was more excellent in the case where the λ/2 plate exhibited reverse wavelength dispersibility.

Further, as understood from the comparison of Examples 9 to 11, it was confirmed that the effect was more excellent in the case where the Nz factor of the λ/2 plate was 0.65 to 0.85.

The order parameters of the mesogenic groups in the λ/2 plate and λ/4 plate used in Example 1 were calculated according to the method described above. The results are shown in Table 4 below.

TABLE 4

Example 1

| | | λ/2 | λ/4 |
|---|---|---|---|
| Order | Sx | 0.286 | 0.299 |
| parameter | Sy | −0.351 | −0.301 |
| | Sz | 0.065 | 0.002 |

### Example 12

A λ/2 plate was prepared according to the same procedure as in the above <<Preparation of λ/2 Plate>>.

<<Preparation (B) of λ/4 Plate>>

A temporary support was prepared according to the method described in the above <<Preparation of λ/2 Plate>>.

The above-mentioned alignment layer coating liquid (A) was continuously applied to the temporary support using a #14 wire bar. The temporary support coated with the alignment layer coating liquid was dried with warm air at 60° C. for 60 seconds and further dried with warm air at 100° C. for 120 seconds, thereby forming a coating film on the temporary support. Further, the coating film was subjected to a rubbing treatment in the longitudinal direction of the temporary support to form an alignment layer.

Next, a composition 6 shown in Table 5 described later was dissolved in MEK to perform preparation such that the concentration of solid contents was 10% by mass. Thus, a coating liquid was obtained. The obtained coating liquid was applied to the alignment layer using a bar coater and heated and aged at 120° C. for 2 minutes. Thus, a homogeneous alignment state of the liquid crystal compound in the coating film was obtained. Then, the coating film was kept at 120° C. and was irradiated with ultraviolet rays at 100 mJ/cm² using a metal halide lamp at 120° C. to form a λ/4 plate (film thickness: 2.2 μm). According to the above procedure, a film C having a temporary support, an alignment layer, and a λ/4 plate was obtained.

<<Preparation of Positive C-Plate>>

A temporary support with an alignment layer was produced according to the method described in the above <<Preparation (B) of λ/4 Plate>>. However, a rubbing treatment was not performed.

Next, a composition 7 shown in Table 5 described later was dissolved in MEK to perform preparation such that the concentration of solid contents was 10% by mass. Thus, a coating liquid was obtained. The obtained coating liquid was applied to the alignment layer using a bar coater and heated and aged at 120° C. for 2 minutes. Thus, a homogeneous alignment state of the liquid crystal compound in the coating film was obtained. Then, the coating film was kept at 120° C. and was irradiated with ultraviolet rays at 100 mJ/cm² using a metal halide lamp at 120° C. to form a positive C-plate (film thickness: 1.1 μm). According to the above procedure, a film D having a temporary support, an alignment layer, and a positive C-plate was obtained.

<<Preparation of Circularly Polarizing Plate>>

The polarizer with a protective film on one surface and the film A were laminated on the polarizer side surface of the obtained polarizer with a protective film on one surface through a commercially available acrylic adhesive (UV-3300 manufactured by Toagosei Co., Ltd.) such that the polarizer faced the λ/2 plate, and thus a laminate was obtained. The laminate was irradiated with ultraviolet rays at an irradiation amount of 100 mJ/cm² from the temporary support side using a metal halide lamp to cure the adhesive. Then, the stretched temporary support was peeled off from the obtained film.

The same procedure was repeated using the films C and D instead of the film A, and the λ/4 plate and the positive C-plate were further laminated on the polarizer. According to the above procedure, a circularly polarizing plate having a polarizer, λ/2 plate, λ/4 plate, and a positive C-plate in this order was prepared.

Each layer was laminated so as to have angles shown in “Angle (°) formed between in-plane slow axis of λ/2 plate and absorption axis of polarizer” and “Angle (°) formed between in-plane slow axis of λ/4 plate and absorption axis of polarizer” shown in Table 6 described later.

### Examples 13 to 17

Circularly polarizing plates were prepared according to the same procedure as in Example 12 except that the values of the Rth and the Nz of the λ/2 plate and the Rth(550) of the positive C-plate were adjusted to the values shown in Table 6.

The obtained circularly polarizing plates of Examples 12 to 17 were used and subjected to the above [Mounting of Circularly Polarizing Plate on Organic EL Display Panel and Evaluation of Display Performance]. The results are shown in Table 6.

The compositions of the compositions 6 and 7 are shown in Table 5.

Each numerical value in Table 5 is expressed in “parts by mass”.

TABLE 5

| | Composition 6 | Composition 7 |
|---|---|---|
| Rod-like liquid crystal compound (2) | 50 | 30 |
| Rod-like liquid crystal compound (4) | 50 | 30 |
| Rod-like liquid crystal compound (1) | | 40 |
| Polymerization initiator 1 | 1.5 | 1.5 |
| Polymerization initiator 2 | 1.5 | 1.5 |
| Vertical alignment agent 3 | | 1 |
| Vertical alignment agent 1 | | 0.5 |
| Polymerizable compound 1 | | 10 |
| Polymerizable compound 2 | 12 | |
| HISOLVE MTEM | 2 | |
| NK ESTER A-200 | 1 | |
| Surfactant 1 | | 0.2 |
| Surfactant 2 | | 0.4 |
| Surfactant 3 | 0.2 | |

Rod-like liquid crystal compound (4)

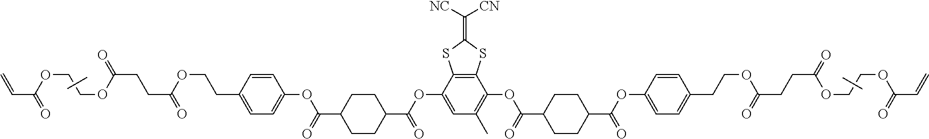

Me position isomer mixture

Vertical alignment agent 3

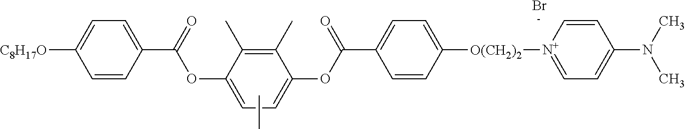

In table 6, as for the column of “Whether or not Expression (1) is satisfied”, a case where Rth(550) which is the retardation of the positive C-plate in the thickness direction at a wavelength of 550 nm satisfies the relationship of Expression (1) is denoted as “A” and a case where Rth(550) does not satisfy the relationship of Expression (1) is denoted as “B”.

As for the column of “Whether or not Expression (2) is satisfied”, a case where Rth(550) which is the retardation of the positive C-plate in the thickness direction at a wavelength of 550 nm satisfies the relationship of Expression (2) is denoted as “A” and a case where Rth(550) does not satisfy the relationship of Expression (2) is denoted as “B”.

TABLE 6

| | | Example 12 | Example 13 | Example 14 | Example 15 | Example 16 | Example 17 |
|---|---|---|---|---|---|---|---|
| λ/2 Plate | Re(550) (nm) | 275 | 275 | 275 | 275 | 275 | 275 |
| | Rth(550) (nm) | −69 | −69 | −69 | 69 | 69 | 69 |
| | Nz | 0.25 | 0.25 | 0.25 | 0.75 | 0.75 | 0.75 |
| | Re(450)/Re(550) | 0.85 | 0.85 | 0.85 | 0.85 | 0.85 | 0.85 |
| | Re(650)/Re(550) | 1.05 | 1.05 | 1.05 | 1.05 | 1.05 | 1.05 |
| | Angle (°) formed between in-plane | 90 | 90 | 90 | 90 | 90 | 90 |
| | slow axis of λ/2 plate and | | | | | | |
| | absorption axis of polarizer | | | | | | |
| λ/4 Plate | Re(550) (nm) | 138 | 138 | 138 | 138 | 138 | 138 |
| | Rth(550) (nm) | 69 | 69 | 69 | 69 | 69 | 69 |
| | Nz | 1 | 1 | 1 | 1 | 1 | 1 |
| | Re(450)/Re(550) | 0.85 | 0.85 | 0.85 | 0.85 | 0.85 | 0.85 |
| | Re(650)/Re(550) | 1.05 | 1.05 | 1.05 | 1.05 | 1.05 | 1.05 |
| | Angle (°) formed between in-plane | 45 | 45 | 45 | 45 | 45 | 45 |
| | slow axis of λ/4 plate and | | | | | | |
| | absorption axis of polarizer | | | | | | |
| Positive C-plate | Re(550) (nm) | 0 | 0 | 0 | 0 | 0 | 0 |
| | Rth(550) (nm) | −69 | −40 | −95 | −69 | −40 | −95 |
| | Whether or not Expression (1) is | A | A | A | A | A | A |
| | satisfied | | | | | | |
| | Whether or not Expression (2) is | A | B | B | A | B | B |
| | satisfied | | | | | | |
| | Rth(450)/Rth(550) | 0.85 | 0.85 | 0.85 | 0.85 | 0.85 | 0.85 |
| | Rth(650)/Rth(550) | 1.05 | 1.05 | 1.05 | 1.05 | 1.05 | 1.05 |
| Display | Reflectivity | A | C | B | A | C | B |
| performance | Change in tint | A | C | C | A | C | C |

As shown in Table 6 above, it was confirmed that in the case of using the circularly polarizing plate having a predetermined layer configuration, the desired effect could be obtained.

Among the examples, it was confirmed that in the case where Rth(550) which is the retardation of the positive C-plate in the thickness direction at a wavelength of 550 nm satisfies the relationship of Expression (2) above, the effect was more excellent.

### EXPLANATION OF REFERENCES

10A, 10B, 10C, 10D: circularly polarizing plate
12: polarizer
14A, 14B: λ/2 plate
16, 22: λ/4 plate
18: organic EL display panel
20: organic EL display device
24: positive C-plate

What is claimed is:

1. An organic electroluminescent display device comprising:
an organic electroluminescent display panel; and
a circularly polarizing plate arranged on the organic electroluminescent display panel,
wherein the circularly polarizing plate has a polarizer, a λ/2 plate, and a λ/4 plate in this order,
an angle formed between an absorption axis of the polarizer and an in-plane slow axis of the λ/4 plate is in a range of 20° to 70°,
an Nz factor of the λ/4 plate is 0.30 to 0.70,
the absorption axis of the polarizer and an in-plane slow axis of the λ/2 plate are orthogonal or parallel to each other,
in a case where the absorption axis of the polarizer and the in-plane slow axis of the λ/2 plate are orthogonal to each other, an Nz factor of the λ/2 plate is 0.10 to 0.40, and
in a case where the absorption axis of the polarizer and the in-plane slow axis of the λ/2 plate are parallel to each other, the Nz factor of the λ/2 plate is 0.60 to 0.90.

2. The organic electroluminescent display device according to claim 1,
wherein in the case where the absorption axis of the polarizer and the in-plane slow axis of the λ/2 plate are orthogonal to each other, the Nz factor of the λ/2 plate is 0.15 to 0.35, and
in the case where the absorption axis of the polarizer and the in-plane slow axis of the λ/2 plate are parallel to each other, the Nz factor of the λ/2 plate is 0.65 to 0.85.

3. The organic electroluminescent display device according to claim 1,
wherein the Nz factor of the λ/4 plate is 0.40 to 0.60.

4. The organic electroluminescent display device according to claim 1,
wherein the λ/2 plate exhibits reverse wavelength dispersibility.

5. The organic electroluminescent display device according to claim 1,
wherein the λ/4 plate exhibits reverse wavelength dispersibility.

6. A circularly polarizing plate comprising, in order:
a polarizer;
a λ/2 plate; and
a λ/4 plate,
wherein an angle formed between an absorption axis of the polarizer and an in-plane slow axis of the λ/4 plate is in a range of 20° to 70°,
an Nz factor of the λ/4 plate is 0.30 to 0.70,
the absorption axis of the polarizer and an in-plane slow axis of the λ/2 plate are orthogonal or parallel to each other,
in a case where the absorption axis of the polarizer and the in-plane slow axis of the λ/2 plate are orthogonal to each other, an Nz factor of the λ/2 plate is 0.10 to 0.40, and
in a case where the absorption axis of the polarizer and the in-plane slow axis of the λ/2 plate are parallel to each other, the Nz factor of the λ/2 plate is 0.60 to 0.90.

7. The circularly polarizing plate according to claim 6,
wherein in the case where the absorption axis of the polarizer and the in-plane slow axis of the λ/2 plate are orthogonal to each other, the Nz factor of the λ/2 plate is 0.15 to 0.35, and
in the case where the absorption axis of the polarizer and the in-plane slow axis of the λ/2 plate are parallel to each other, the Nz factor of the λ/2 plate is 0.65 to 0.85.

8. The circularly polarizing plate according to claim 6,
wherein the Nz factor of the λ/4 plate is 0.40 to 0.60.

9. The circularly polarizing plate according to claim 6,
wherein the λ/2 plate exhibits reverse wavelength dispersibility.

10. The circularly polarizing plate according to claim 6,
wherein the λ/4 plate exhibits reverse wavelength dispersibility.

11. The circularly polarizing plate according to claim 6 that is used for antireflection application.

12. An organic electroluminescent display device comprising:
an organic electroluminescent display panel; and
a circularly polarizing plate arranged on the organic electroluminescent display panel,
wherein the circularly polarizing plate has a polarizer, a λ/2 plate, a λ/4 plate, and a positive C-plate in this order,
an angle formed between an absorption axis of the polarizer and an in-plane slow axis of the λ/4 plate is in a range of 20° to 70°,
a retardation Rth(550) of the positive C-plate in a thickness direction at a wavelength of 550 nm satisfies a relationship of Expression (1),
−{(in-plane retardation of the λ/4 plate at a wavelength of 550 nm)×½+30 nm}≤Rth(550)≤−{(in-plane retardation of the λ/4 plate at a wavelength of 550 nm)×½−30 nm} Expression (1)
the absorption axis of the polarizer and an in-plane slow axis of the λ/2 plate are orthogonal or parallel to each other,
in a case where the absorption axis of the polarizer and the in-plane slow axis of the λ/2 plate are orthogonal to each other, an Nz factor of the λ/2 plate is 0.10 to 0.40, and
in a case where the absorption axis of the polarizer and the in-plane slow axis of the λ/2 plate are parallel to each other, the Nz factor of the λ/2 plate is 0.60 to 0.90.

13. The organic electroluminescent display device according to claim 12,
wherein the retardation Rth(550) of the positive C-plate in the thickness direction at a wavelength of 550 nm satisfies a relationship of Expression (2).
−{(in-plane retardation of the λ/4 plate at a wavelength of 550 nm)×½+15 nm}≤Rth(550)≤−{(in-plane retardation of the λ/4 plate at a wavelength of 550 nm)×½−15 nm} Expression (2)

14. The organic electroluminescent display device according to claim 12,
wherein the λ/2 plate exhibits reverse wavelength dispersibility.

15. The organic electroluminescent display device according to claim 12,
wherein the λ/4 plate exhibits reverse wavelength dispersibility.

16. A circularly polarizing plate comprising, in order:
a polarizer;
a λ/2 plate;
a λ/4 plate; and
a positive C-plate,
wherein an angle formed between an absorption axis of the polarizer and an in-plane slow axis of the λ/4 plate is in a range of 20° to 70°,
a retardation Rth(550) of the positive C-plate in a thickness direction at a wavelength of 550 nm satisfies a relationship of Expression (1),
−{(in-plane retardation of the λ/4 plate at a wavelength of 550 nm)×½+30 nm}≤Rth(550)≤−{(in-plane retardation of the λ/4 plate at a wavelength of 550 nm)×½−30 nm} Expression (1)
the absorption axis of the polarizer and an in-plane slow axis of the λ/2 plate are orthogonal or parallel to each other,
in a case where the absorption axis of the polarizer and the in-plane slow axis of the λ/2 plate are orthogonal to each other, an Nz factor of the λ/2 plate is 0.10 to 0.40, and
in a case where the absorption axis of the polarizer and the in-plane slow axis of the λ/2 plate are parallel to each other, the Nz factor of the λ/2 plate is 0.60 to 0.90.

17. The circularly polarizing plate according to claim 16,
wherein the retardation Rth(550) of the positive C-plate in the thickness direction at a wavelength of 550 nm satisfies a relationship of Expression (2).
−{(in-plane retardation of the λ/4 plate at a wavelength of 550 nm)×½+15 nm}≤Rth(550)≤−{(in-plane retardation of the λ/4 plate at a wavelength of 550 nm)×½−15 nm} Expression (2)

18. The circularly polarizing plate according to claim 16,
wherein the λ/2 plate exhibits reverse wavelength dispersibility.

19. The circularly polarizing plate according to claim 16,
wherein the λ/4 plate exhibits reverse wavelength dispersibility.

20. The circularly polarizing plate according to claim 16 that is used for antireflection application.
